(19) United States
(12) Patent Application Publication
(10) Pub. No.: US 2014/0130845 A1
(43) Pub. Date: May 15, 2014

(54) CONCENTRATOR PHOTOVOLTAIC DEVICE AND METHOD FOR MANUFACTURING CONCENTRATOR PHOTOVOLTAIC DEVICE

(71) Applicant: Kazuki Ohki, Osaka-shi (JP)

(72) Inventor: Kazuki Ohki, Osaka-shi (JP)

(73) Assignee: SHARP KABUSHIKI KAISHA, Osaka,-shi, Osaka (JP)

(21) Appl. No.: 14/130,187

(22) PCT Filed: May 23, 2012
(86) PCT No.: PCT/JP2012/063132

§ 371 Date: Dec. 30, 2013

(30) Foreign Application Priority Data
Jun. 29, 2011 (JP) 2011-144707

(51) Int. Cl. H01L 31/052; H01L 31/18

(52) U.S. Cl. CPC H01L 31/0524; H01L 31/1876
USPC 136/246; 438/65

(57) ABSTRACT

A concentrator photovoltaic device includes a concentrating lens that concentrates sunlight, a solar cell element that photoelectrically converts the sunlight concentrated by the concentrating lens, a mounting substrate on which the solar cell element is mounted, a concentrating lens array formed by the concentrating lenses respectively in a row direction (Dx) and a column direction (Dy), and a heat diffusion plate on which the mounting substrates are mounted to diffuse heat from the mounting substrates. The heat diffusion plate is disposed facing the concentrating lens disposed in the row direction (Dx). A size (SPx) of the heat diffusion plate in the row direction (Dx) is two or more times as large as a size (SLx) of each concentrating lens in the row direction (Dx), and a size (SPy) of the heat diffusion plate in the column direction (Dy) is smaller than a size (SLy) of each concentrating lens in the column direction (Dy)

### TECHNICAL FIELD

The present invention relates to a concentrator photovoltaic device that includes solar cell elements that photoelectrically convert sunlight concentrated by respective concentrating lenses, and mounting substrates on which the respective solar cell elements are mounted. The present invention also relates to a method for manufacturing the concentrator photovoltaic device.

### BACKGROUND ART

Photovoltaic devices generally have a non-concentrator and fixed flat-plate structure in which a photovoltaic device including a plurality of solar cell elements that is arranged with no space between them is installed on a roof or the like. Techniques for reducing the number of solar cell elements included in the photovoltaic device have been proposed because the solar cell element costs higher than other members (parts) of the device.

Specifically, there is a proposed technique of concentrating sunlight using an optical lens, a reflecting mirror, or the like, and irradiating a small area of solar cell elements with the concentrated sunlight, to increase generated electrical power per unit area of the solar cell elements, thereby reducing the cost of the solar cell elements (i.e., the electrical power generation cost of the photovoltaic device).

In general, as the concentration ratio increases, the photoelectric conversion efficiency of a solar cell element increases. If, however, the position of the solar cell element is fixed, sunlight is incident at an oblique angle in most time and cannot be efficiently used. Therefore, a tracking concentrator photovoltaic device has been proposed that tracks the sun so that the front surface of the device is invariably normal to sunlight, thereby achieving a high concentration ratio (see, for example, Patent Documents 1-5).

FIG. 6A is a schematic plain view showing a schematic structure of a main part of a conventional concentrator photovoltaic device.

FIG. 6B is a schematic side view along a longitudinal direction of the main part of the concentrator photovoltaic device shown in FIG. 6A.

In a concentrator photovoltaic device 100, a heat dissipation layer 134 is fixed to a surface of a base plate 128 made of a plate-like aluminum alloy. On a surface of the heat dissipation layer 134, a metal foil 158 longitudinally patterned is disposed. To one end (one end in the longitudinal direction) of the metal foil 158, a substrate side of a solar cell 130 is adhered, and the other end (the other end in the longitudinal direction) of the metal foil 158 is separated from the heat dissipation layer 134 and connected to a front surface electrode 142 of an adjacent solar cell 130. That is, the solar cells 130 are connected to each other in series (see, for example, Patent Document 4).

The heat dissipation layer 134 is made of epoxy resin in which is dispersed a filling material that includes at least one of carbon, glass fiber and metal powder, i.e., a filler for enhancing heat conductivity. Also, the heat dissipation layer 134 has a thickness of about 100 μm, a heat conductivity of about 5.0 W/m·K, and a volume resistivity of about 1×10¹⁵ Ω·cm. With such a configuration, there are proposals that the heat dissipation of the solar cell 130 heated by the concentrating operation is effectively performed and that the heat dissipation layer 134 has an advantageous effect of an insulating layer that electrically insulates the solar cell 130 and the metal foil 158 from the base plate 128.

However, it is known that insulation resistance of epoxy resin decreases with a rise in temperature. Although the insulation resistance also depends on features of the resin and environmental conditions, but for example, when the volume resistivity is 10¹⁵ Ω·cm at 20° C., if the temperature is elevated to 100° C., the volume resistivity decreases to 10¹² Ω·cm. The decrease of the volume resistivity with a rise in temperature causes the insulation resistance between the metal foil 158 and the base plate 128 to decrease, thus it may degrade reliability.

Also, heat of the solar cell 130 heated by the concentrating operation diffuses in the metal foil 158 to reach the base plate 128 via the heat dissipation layer 134, and further is dissipated in the air while being diffused in the base plate 128. The metal foil 158 is made of copper foil (a heat conductivity of about 400 W/m·K), and has a thickness of about 100 μm. The base plate 128 is made of aluminum alloy (a heat conductivity of about 200 W/m·K), and has a thickness of about 2 to 5 mm. Thus, heat diffusion in the horizontal direction is basically performed by the base plate 128.

That is, the metal foil 158 contributes to heat dissipation only at a part in the vicinity of the solar cell 130. The epoxy resin containing a heat conductive filler at the lower side of the metal foil 158 that hardly contributes to the heat dissipation is over-engineering in respect of the heat dissipation. The production cost of the epoxy resin containing the heat conductive filler is remarkably higher than that of the ordinary epoxy resin, thereby being a cause that prevents the concentrator photovoltaic device from being produced with low costs. It is possible to have a configuration in which the epoxy resin containing the heat conductive filler is used in the region facing the solar cell 130 and on the lower side of the metal foil 158, and the ordinary epoxy resin is used in the other region. But such a configuration requires complicated processes. Furthermore, an interface is generated between the epoxy resin containing the heat conductive filler and the ordinary epoxy resin, thus it may difficult to obtain reliability.

Also, the concentrator photovoltaic device 100 has a configuration in which the metal foil 158 formed by copper foil and the base plate 128 formed by aluminum alloy are adhered by the epoxy resin layer containing the heat conductive filler (the heat dissipation layer 134) interposed therebetween. The metal foil 158 and the base plate 128 respectively have different coefficients of linear expansion. Thus, when a temperature change cycle occurs, strong stress is applied mainly to the epoxy resin layer (the heat dissipation layer 134) and the metal foil 158. In the result, the epoxy resin layer (the heat dissipation layer 134) and the metal foil 158 may be peeled or cracked.

FIG. 7A is a schematic plain view showing a schematic structure of a main part of a conventional solar cell.

FIG. 7B is a schematic cross-sectional view showing a cross-sectional state taken along arrows B-B in FIG. 7A.

The conventional solar cell 200 includes a solar cell element 211 and a receiver substrate 220 on which the solar cell element 211 is mounted. The receiver substrate 220 includes a base 221, an intermediate insulating layer 222 laminated on the base 221 and a connecting pattern layer 223 laminated on the intermediate insulating layer 222. For example, the receiver substrate 220 has a size of 40 mm to 80 mm square when the solar cell element 211 has a size of 8 to 10 mm. In the receiver substrate 220, one solar cell element 211 is die-bonded to the connecting pattern layer 223 by solder and the like.

On the connecting pattern layer 223 of the receiver substrate 220, in a region other than regions where electrical connection is needed (a surface electrode extraction terminal 224, a substrate electrode extraction terminal 225, a substrate electrode connecting portion 223bc, a surface electrode connecting portion 223sc and the like), a surface protection layer 227 is formed. Leads are connected by solder or the like to the surface electrode extraction terminal 224 and the substrate electrode extraction terminal 225 of the receiver substrate 220 so as to connect the adjacent receiver substrates 220 to each other.

In the solar cell 200, a covering portion 230 that protects the solar cell element 211 is formed. Also, in the receiver substrate 220, a pair of joint mounting holes 220h is diagonally formed, by which the solar cell 210 is mounted on and fixed to the solar cell mounting plate (the housing frame: not shown). The receiver substrate 220 is fixed to the solar cell mounting plate by rivets and the like.

With this configuration, external connection terminals (the surface electrode extraction terminal 224 and the substrate electrode extraction terminal 225) of the solar cell element 211 can be extracted from the connecting pattern layer 223. Thus, the solar cell element 211 can be insulated from the base 221, and the base 221 can be used effectively as a heat dissipation means. Therefore, realization of high reliability and electrical power generation efficiency has been proposed.

However, in the photovoltaic unit in which the solar cell 200 is mounted on the solar cell mounting plate, the joint mounting holes 220h are mechanically fastened to respective holes (not shown) of the housing frame (the solar cell mounting plate) using fastening members such as rivets. For this reason, the receiver substrate 220 should be made more largely according to areas that the joint mounting holes 220h and the fastening members occupy, an area of space regions required for electrically insulating the fastening members (the joint mounting holes 220h) and the connecting pattern layer 223, and the like. Thus, cost reduction of the solar cell 200 has been required. Also, in the photovoltaic unit in which the solar cell 200 is mounted on the solar cell mounting plate, one receiver substrate 220 is fastened using two joint mounting holes 220h. Thus, a number of fastening members such as rivets are needed, which results in a high cost of fastening members such as rivets. Also, in the photovoltaic unit in which the solar cell 200 is mounted on the solar cell mounting plate, since many fastening members are used, it takes a long time to fasten the receiver substrate 220. Thus, there has been a problem of productivity.

### CITATION LIST

### Patent Literatures

[Patent Literature 1] JP 2002-289896 A
[Patent Literature 2] JP 2002-289897 A
[Patent Literature 3] JP 2002-289898 A
[Patent Literature 4] JP 2003-174179 A
[Patent Literature 5] JP 2008-091440 A

### SUMMARY OF INVENTION

### Technical Problem

The present invention was made in consideration of such circumstances, and an object thereof is to provide a concentrator photovoltaic device which includes the heat diffusion plate on which is mounted solar cell elements (and mounting substrates), so that heat dissipation properties are improved and a temperature rise of the solar cell elements is effectively restricted, thus a high photoelectric conversion efficiency can be obtained.

Another object of the present invention is to provide a method for effectively manufacturing, with high productivity, a concentrator photovoltaic device having high heat dissipation.

### Solution to Problem

The concentrator photovoltaic device according to the present invention includes: concentrating lenses concentrating sunlight; solar cell elements photoelectrically converting the sunlight concentrated by the respective concentrating lenses; and mounting substrates on which the respective solar cell elements are mounted. The concentrator photovoltaic device further includes a concentrating lens array formed by the concentrating lenses respectively arranged in a row direction and a column direction, and a heat diffusion plate that diffuses heat from the mounting substrates. The mounting substrates are mounted on the heat diffusion plate. The heat diffusion plate is disposed facing the concentrating lenses arranged in the row direction. A size of the heat diffusion plate in the row direction is two or more times as large as a size of each of the concentrating lenses in the row direction, and a size of the heat diffusion plate in the column direction is smaller than a size of each of the concentrating lenses in the column direction.

The concentrator photovoltaic device according to the present invention includes the heat diffusion plate on which the solar cell elements (and the mounting substrates) are mounted. Thus, even if intensities of the concentrated sunlight incident on the solar cell elements (the mounting substrates) differ from each other, and heated states of the solar cell elements differ from each other, heat is dissipated from the heat diffusion plate so that the heated states of the solar cell elements are equalized. In the result, heat dissipation properties of the concentrator photovoltaic device are improved so that a temperature rise of the solar cell element is effectively suppressed, thereby output deterioration by the rise in temperature of the solar cell element is suppressed to obtain a high photoelectric conversion efficiency.

The concentrator photovoltaic device according to a preferable aspect of the present invention further includes a housing frame on which the heat diffusion plate is mounted.

Therefore, in the concentrator photovoltaic device according to a preferable aspect of the present invention, the heat diffusion plate on which the mounting substrates are mounted makes contact with the housing frame, thus, when heat from the heat diffusion plate (the mounting substrates) is dissipated to the outside of the concentrator photovoltaic device, a heat dissipation area (a surface area of the housing frame) can be enlarged. Therefore, heat of the heat diffusion plate (the mounting substrates) can be effectively dissipated to the outside of the concentrator photovoltaic device so that the heat dissipation of the concentrator photovoltaic device can be further improved.

Also, the concentrator photovoltaic device according to a preferable aspect of the present invention further includes adhering-fixing portions that adhere and fix the mounting substrates to the heat diffusion plate.

Thus, in the concentrator photovoltaic device according to a preferable aspect of the present invention, the mounting substrate is fixed to the heat diffusion plate via the adhering-fixing portion (an adhesive) that has an area substantially equal to the mounting substrate. Therefore, it is not necessary to form, on the mounting substrate, a region (for example, a fastening region) for mechanically fixing the mounting substrate to the heat diffusion plate. Thus, the mounting substrate can be made small. Furthermore, heat from the mounting substrate can be smoothly dissipated to the heat diffusion plate via the adhering-fixing portion.

Also, in the concentrator photovoltaic device according to a preferable aspect of the present invention, the mounting substrates includes conductors to which the respective solar cell elements are connected and insulators on which the respective conductors are disposed.

Thus, in the concentrator photovoltaic device according to a preferable aspect of the present invention, the solar cell elements are mounted on the respective mounting substrates (the conductors mounted on the respective insulators), thus, the solar cell elements are mounted on the respective stable-shaped conductors, and the conductors are insulated from the heat diffusion plate via the respective insulators. Thus, the solar cell elements are reliably insulated from the heat diffusion plate. And, when the solar cell elements are disposed on the heat diffusion plate, high insulation properties can be ensured between the solar cell elements.

Also, in the concentrator photovoltaic device according to a preferable aspect of the present invention, a volume resistivity of the insulators is 10¹² Ω·cm or more.

Thus, in the concentrator photovoltaic device according to a preferable aspect of the present invention, insulation of the mounting substrate is reliably realized, thus high insulation between the solar cell elements can be ensured.

Also, in the concentrator photovoltaic device according to a preferable aspect of the present invention, the insulators are made of a ceramic material.

Thus, in the concentrator photovoltaic device according to a preferable aspect of the present invention, insulation of the mounting substrate can be easily realized.

Also, in the concentrator photovoltaic device according to a preferable aspect of the present invention, the ceramic material is aluminum nitride.

Thus, in the concentrator photovoltaic device according to a preferable aspect of the present invention, high insulation and a high heat conductivity are ensured. Furthermore, the conductor can be easily formed by aluminum (or aluminum alloy).

Also, the concentrator photovoltaic device according to a preferable aspect of the present invention further includes a connecting wiring that connects one of the conductors of the mounting substrates to an adjacent one of the conductors of the mounting substrates. And the connecting wiring includes a connecting conductor that connects the conductors to each other and an insulating coating material that coats the connecting conductor.

Thus, in the concentrator photovoltaic device according to a preferable aspect of the present invention, the conductors of the adjacent mounting substrates are connected to each other via the connecting conductor that is coated by the insulating coating material. Thus, it is possible to prevent the connecting conductor from making contact with another conductive region, thereby improving connection reliability.

Also, in the concentrator photovoltaic device according to a preferable aspect of the present invention, the connecting conductor is disposed in a form of a beam between the conductors.

Thus, in the concentrator photovoltaic device according to a preferable aspect of the present invention, since the connecting conductor coated by the insulating coating material is disposed in a form of a beam, the connecting conductor can be reliably prevented from making contact with another conductive region. Thus, connection reliability between the solar cell elements can be further improved.

Also, in the concentrator photovoltaic device according to a preferable aspect of the present invention, the connecting conductor is connected to the conductors by welding.

Thus, in the concentrator photovoltaic device according to a preferable aspect of the present invention, the connecting conductor is connected to the conductor by welding. Thus, it is possible to enhance connection strength and improve reliability compared to solder connection. Also, in contrast to the solder connection, it is possible to reduce the connecting region (to save space), thus the mounting substrate can be reliably made small.

Also, in the concentrator photovoltaic device according to a preferable aspect of the present invention, the conductors and the connecting conductor are formed by the same metal material.

Thus, in the concentrator photovoltaic device according to a preferable aspect of the present invention, since the conductor and the connecting conductor are formed by the same metal material, the connection becomes easy. Also, it is possible that the welding having a connection strength higher than those of the different metals can be performed, thereby obtaining further higher reliability.

Also, in the concentrator photovoltaic device according to a preferable aspect of the present invention, the heat diffusion plate and the connecting conductor are formed by the same metal material.

Thus, in the concentrator photovoltaic device according to a preferable aspect of the present invention, since heat diffusion plate and the connecting conductor are formed by the same metal material, when the heat diffusion plate and the connecting wiring (connecting conductor) become high temperature by the light concentrating function, or when the device is installed in an environment where there is large variation in the outside temperature, difference in changes due to temperature change of the heat diffusion plate and the connecting conductor, which are remarkably affected by the coefficient of linear expansion, is suppressed. Thus, connection reliability can be improved.

Also, the concentrator photovoltaic device according to a preferable aspect of the present invention further includes connecting members formed by a metal material. The conductors are made up of respective first conductors on which the respective solar cell elements are mounted and respective second conductors that are disposed separated apart from the respective first conductors. The solar cell elements include front surface electrodes that are formed on respective front surfaces of the solar cell elements. The second conductors and the front surface electrodes are respectively connected by the connecting members.

Thus, in the concentrator photovoltaic device according to a preferable aspect of the present invention, the front surface electrode of the solar cell element and the second conductor can be easily connected.

Also, in the concentrator photovoltaic device according to a preferable aspect of the present invention, the metal material is aluminum or aluminum alloy.

Thus, in the concentrator photovoltaic device according to a preferable aspect of the present invention, weight and cost saving of the concentrator photovoltaic device becomes possible in comparison with the case in which copper or copper alloy is used as the metal material. Furthermore, because of high corrosion resistance of the metal material, reliability is improved.

Also, in the concentrator photovoltaic device according to a preferable aspect of the present invention, the adhering-fixing portions are formed by a synthetic resin material having a heat conductivity of 1 W/m·K or more.

Thus, in the concentrator photovoltaic device according to a preferable aspect of the present invention, the mounting substrate is adhered to the heat diffusion plate via the adhering-fixing portion having a high heat conductivity. Thus, heat brought to the solar cell element (mounting substrate) can be effectively conducted to the heat diffusion plate.

Also, the concentrator photovoltaic device according to a preferable aspect of the present invention further includes: a pillar-shaped light guide portion guiding sunlight concentrated by each of the concentrating lenses to a corresponding one of the solar cell elements; and a light shielding plate having an inserting hole into which the pillar-shaped light guide portion is inserted, and being fastened to the heat diffusion plate so as to shield sunlight.

Thus, in the concentrator photovoltaic device according to a preferable aspect of the present invention, sunlight concentrated by the concentrating lens is further concentrated by the pillar-shaped light guide portion, thereby, the concentrated sunlight is uniformized. Also, when position deviation and angle deviation in light concentration by the concentrating lens are generated, sunlight can be concentrated to the solar cell element with high accuracy. Also, in the concentrator photovoltaic device according to a preferable aspect of the present invention, the light shielding plate is disposed around the pillar-shaped light guide portion. Thus, when sunlight is concentrated abnormally, it is possible to prevent a light concentration spot from being irradiated on the connecting wiring or the resin sealing portion.

Also, in the concentrator photovoltaic device according to a preferable aspect of the present invention, the light shielding plate is formed by the same metal material as used for the heat diffusion plate.

Thus, in the concentrator photovoltaic device according to a preferable aspect of the present invention, the heat diffusion plate and the light shielding plate are formed by the same metal material, so it is possible to suppress the interference between the inserting hole of the light shielding plate (for example, made of a metal material) and the pillar-shaped light guide portion (for example, made of a glass material) caused by the difference in the coefficient of linear expansion therebetween. Thereby, the stress applied to the attaching portion that attaches the pillar-shaped light guide portion to the solar cell element can be suppressed. Thus, it is possible to prevent the solar cell element or the optical system (the pillar-shaped light guide portion and the attaching portion) from being damaged.

Also, in a method for manufacturing a concentrator photovoltaic device according to the present invention, the concentrator photovoltaic device includes: solar cell elements photoelectrically converting sunlight concentrated by respective concentrating lenses; mounting substrates having respective conductors to which the respective solar cell elements are connected, the mounting substrates on which the respective solar cell elements are mounted; a concentrating lens array formed by the concentrating lenses respectively arranged in a row direction and a column direction; a heat diffusion plate that diffuses heat from the mounting substrates, the heat diffusion plate on which the mounting substrates are mounted; and a housing frame on which the heat diffusion plate is mounted. The method for manufacturing the concentrator photovoltaic device includes the steps of: mounting, on the heat diffusion plate, the mounting substrates on which the respective solar cell elements are mounted; connecting one of the conductors of the mounting substrates mounted on the heat diffusion plate to an adjacent one of the conductors of the mounting substrates by a connecting wiring, and mounting the heat diffusion plate, to which the conductors are connected by the connecting wirings, on the housing frame so that a longitudinal direction of the heat diffusion plate corresponds to the row direction of the concentrating lens array.

Thus, in the method for manufacturing the concentrator photovoltaic device according to the present invention, the heat diffusion plate on which the mounting substrates are mounted is attached to the housing frame so that the longitudinal direction of the heat diffusion plate corresponds to the row direction of the concentrating lens array. Thus, it is possible to efficiently manufacture, with high productivity, the concentrator photovoltaic device having high heat dissipation.

In the method for manufacturing the concentrator photovoltaic device according to the present invention, preferably, the heat diffusion plate is disposed facing the concentrating lenses disposed in the row direction. A size of the heat diffusion plate in the row direction is two or more times as large as a size of each of the concentrating lenses in the row direction, and a size of the heat diffusion plate in the column direction is smaller than a size of each of the concentrating lenses in the column direction. Thus, it is possible to efficiently manufacture, with high productivity, the concentrator photovoltaic device having high heat dissipation according to the present invention.

### Advantageous Effects of Invention

The concentrator photovoltaic device according to the present invention includes the heat diffusion plate on which the solar cell elements (and the mounting substrates) are mounted. Thus, even if intensities of the concentrated sunlight incident on the solar cell elements (the mounting substrates) differ from each other, and heated states of the solar cell elements differ from each other, heat is dissipated from the heat diffusion plate so that the heated states of the solar cell elements are equalized. In the result, in the concentrator photovoltaic device according to the present invention, heat dissipation properties are improved so that the temperature rise of the solar cell element is effectively suppressed, thereby output deterioration by the rise in temperature of the solar cell element is suppressed to obtain a high photoelectric conversion efficiency.

Also, in a method for manufacturing the concentrator photovoltaic device according to the present invention, the heat diffusion plate on which the mounting substrates are mounted is attached to the housing frame so that the longitudinal direction of the heat diffusion plate corresponds to the row direction of the concentrating lens array. Thus, it is possible to effectively manufacture, with high productivity, the concentrator photovoltaic device having high heat dissipation.

### BRIEF DESCRIPTION OF DRAWINGS

FIG. 1A is a plain view showing a disposed state of concentrating lenses that constitute a concentrating lens array provided in a concentrator photovoltaic device according to an embodiment of the present invention.

FIG. 1B is a plain view showing a disposed state of heat diffusion plates provided in a bottom portion of a housing frame of the concentrator photovoltaic device according to an embodiment of the present invention.

FIG. 2A is a cross-sectional view showing an overlapped state of components taken from arrows A-A in FIG. 1B.

FIG. 2B is an enlarged cross-sectional view showing the disposed state of the solar cell element shown in FIG. 2A.

FIG. 3 is a plain view showing a connecting state of connecting wirings relative to the solar cell element shown in FIG. 2B.

FIG. 4A is an enlarged plain view showing a main configuration of the concentrator photovoltaic device according to an embodiment of the present invention.

FIG. 4B is a cross-sectional view showing a cross-section taken from arrows B-B in FIG. 4A.

FIG. 5 is an enlarged cross-sectional view showing a modified example of the concentrator photovoltaic device 1 according to the embodiment of the present invention in a state similar to FIG. 2B.

FIG. 6A is a schematic plain view showing a schematic configuration of a main part of a conventional concentrator photovoltaic device.

FIG. 6B is a schematic side view of the main part of the concentrator photovoltaic device shown in FIG. 6A viewed from a longitudinal direction.

FIG. 7A is a schematic plain view showing a schematic configuration of a main part of a conventional solar cell.

FIG. 7B is a schematic cross-sectional view showing a cross-section taken from arrows B-B in FIG. 7A.

### DESCRIPTION OF EMBODIMENTS

Hereinafter, specific embodiments of the present invention will be described with reference to the accompanying drawings.

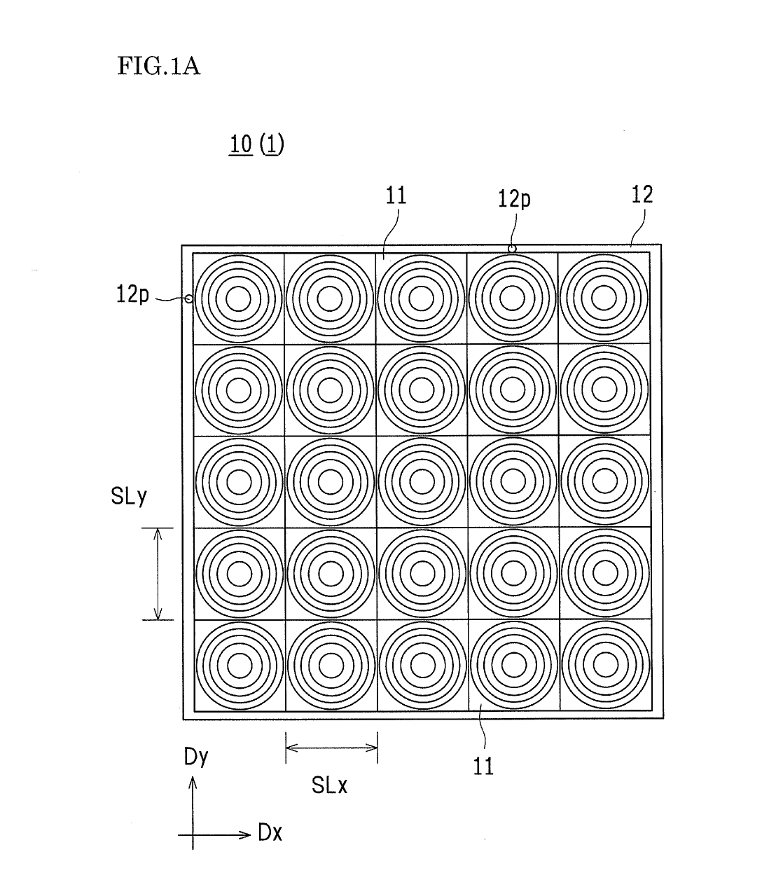

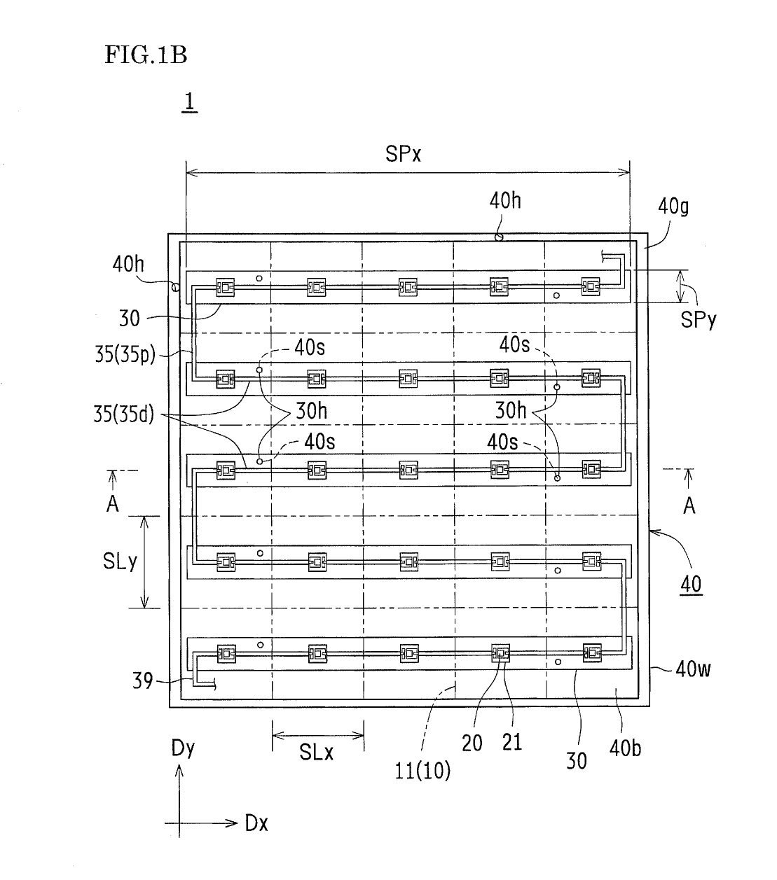

A concentrator photovoltaic device and a method for manufacturing the concentrator photovoltaic device according to the present embodiment will be described with reference to the FIGS. 1A to 4B.

FIG. 1A is a plain view showing a disposed state of concentrating lenses 11 that constitute a concentrating lens array 10 provided in a concentrator photovoltaic device 1 according to the present embodiment of the present invention.

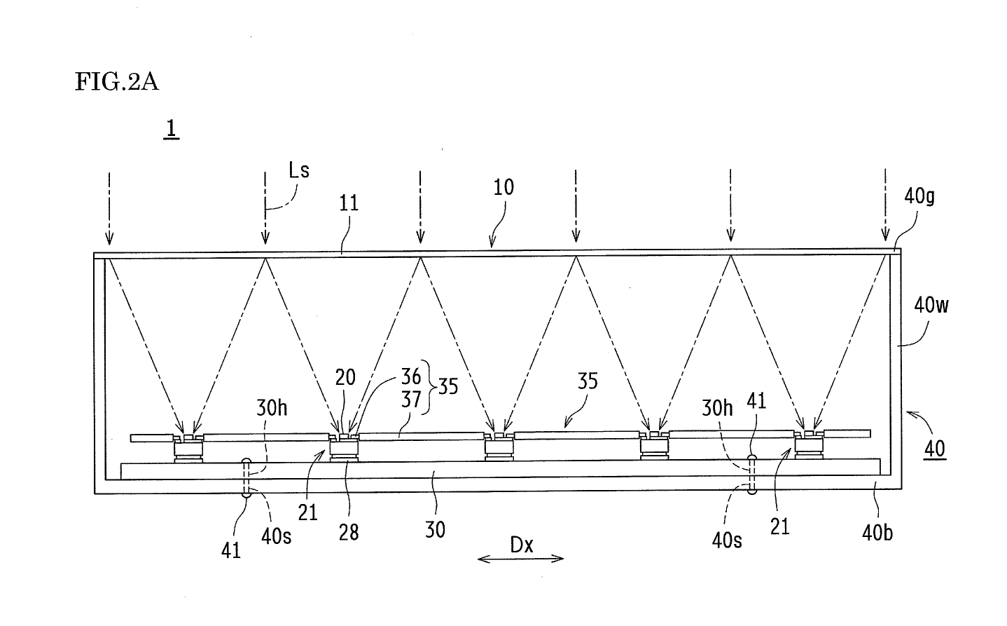

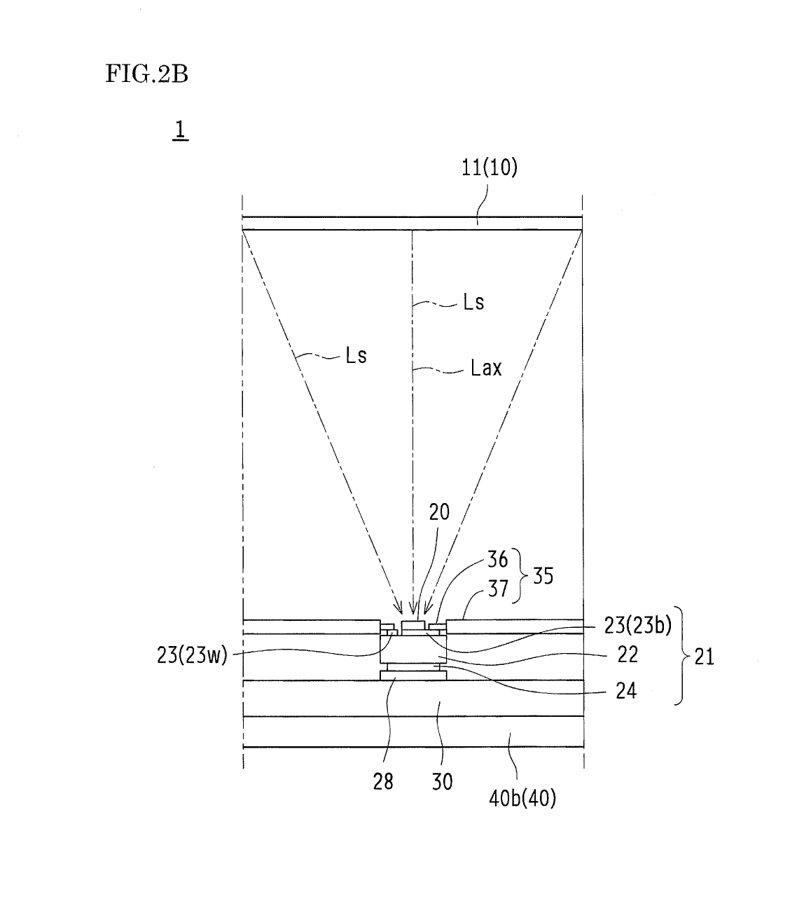

The concentrator photovoltaic device 1 according to the present embodiment includes the concentrating lens array 10 in which concentrating lenses 11 concentrating sunlight Ls (see FIG. 2A) are respectively disposed in a row direction Dx as well as a column direction Dy. That is, the concentrating lens array 10 is formed by arranging the concentrating lenses 11 in a matrix shape on a flat surface of a light transmitting substrate 12.

The light transmitting substrate 12 is formed, for example, by a reinforced glass plate. The concentrating lens 11 is formed, for example, by acrylic resin and the like. The concentrating lens 11 may be formed separately one by one, but also a plurality of concentrating lenses 11 may be formed as a one plate. A size SLx of each concentrating lens 11 in the row direction Dx and a size SLy of each concentrating lens 11 in the column direction Dy are, for example, in a range of about 50 mm to 250 mm. The concentrating lenses 11 have an adequate rectangular shape such as a square or a rectangle. In the present embodiment, the concentrating lenses 11 have a square shape, and each of the sizes SLx and SLy is 170 mm. The concentrating lens 11 is a fresnel lens.

The size of the concentrating lens array 10 is determined by specifications that the concentrator photovoltaic device 1 requires. It is set taking into consideration loss of concentration efficiency by bending of the concentrating lens array 10, productivity of the concentrating lens array 10 and the like. In this embodiment, the concentrating lens array 10 is made by the square-shaped concentrating lenses 11 that are arranged, five in the row direction and five in the column direction, i.e., 5×5 (=25) lenses are disposed. Thus, the concentrating lens array 10 has an external size of 850 mm×850 mm.

In some parts (external peripheral ends) of the light transmitting substrate 12, positioning projections 12p are formed, which position the concentrating lens array 10 at the housing frame 40 (positioning holes 40h, see FIG. 1B). At least two of the positioning projections 12p are needed, and preferably are disposed at different sides of the light transmitting substrate 12 for the purpose of improving positioning accuracy.

FIG. 1B is a plain view showing a disposed state of heat diffusion plates 30 provided in a bottom portion 40b of a housing frame 40 of the concentrator photovoltaic device 1 according to the present embodiment.

The concentrator photovoltaic device 1 according to the present embodiment includes the housing frame 40. The housing frame 40 includes the bottom portion 40b on which are mounted the heat diffusion plates 30 that diffuse heat from solar cell elements 20 (mounting substrates 21), and a wall portion 40w on which the concentrating lens array 10 is disposed so as to face the bottom portion 40b (the heat diffusion plates 30). The top surface of the wall portion 40w includes a flange portion 40g on which the concentrating lens array 10 is disposed. The flange portion 40g has the positioning holes 40h formed so as to correspond to the positioning projections 12p of the light transmitting substrate 12.

On the heat diffusion plate 30, is mounted a plurality of (in the present embodiment, five) mounting substrate 21 on which the respective solar cell elements 20 are mounted. The solar cell elements 20 are connected to each other by connecting wirings 35. There are two kinds of connecting wirings 35, one is a connecting wiring 35d to connect to each other the solar cell elements 20 (the mounting substrates 21) mounted on the same heat diffusion plate 30, and the other is a connecting wiring 35p to connect to each other the solar cell elements 20 (mounting substrates 21) mounted respectively on the adjacent heat diffusion plates 30. Hereinafter, when it is not necessary to specifically distinguish the connecting wiring 35d from the connecting wiring 35p, both are described simply as the connecting wiring 35.

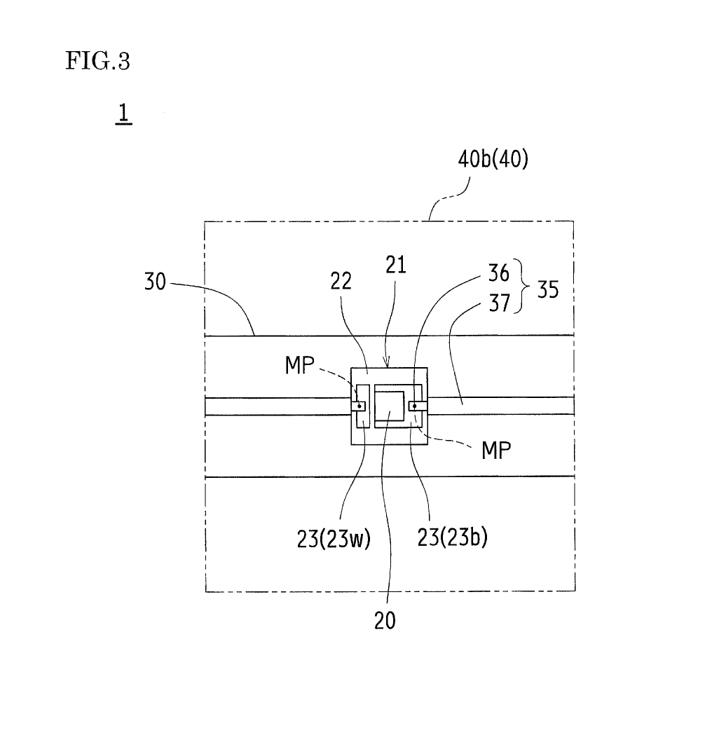

The connecting wiring 35d and the connecting wiring 35p are disposed in a form of a beam (bar), that is, they do not make contact with a surface of the heat diffusion plate 30 and a surface of the bottom portion 40b. Since the connecting wiring 35p is a wiring between the adjacent heat diffusion plates 30, it has a U-shaped folding shape. The connecting wiring 35 is connected, by welding (for example, ultrasonic welding), to a conductor 23 (a first conductor 23b and a second conductor 23w, see FIGS. 2B and 3. Hereinafter, when it is not necessary to specifically distinguish the first conductor 23b from the second conductor 23w, both are simply described as the conductor 23) that is included in the mounting substrate 21.

The solar cell elements 20 are shown, for example, in a series connection state, but they are possible to be in a parallel connection state between different heat diffusion plates 30. Among the solar cell elements 20 connected in series, to the endmost solar cell element 20 (the conductor 23 of the mounting substrate 21 (see FIG. 3)), a power extraction wiring 39 is connected by welding (for example, by ultrasonic welding) so as to output electrical power generated by the concentrator photovoltaic device 1.

The size SPx of the heat diffusion plate 30 in the row direction Dx is larger than the size SLx of each concentrating lens 11 in the row direction Dx. The size SPx is at least two or more times as large as the size SLx. As the size SPx is at least two or more times as large as the size SLx, the heat diffusion plate 30 can be disposed for at least two concentrating lens 11. Thus, the mounting substrate 21 can be efficiently mounted on the heat diffusion plate 30. Also, heat dissipation from the heat diffusion plate 30 can be improved. Furthermore, attachment of the heat diffusion plate 30 to the housing frame 40 can be simplified.

The maximum value of the size SPx is determined by the disposed number of the concentrating lenses 11 in the row direction Dx of the concentrating lens array 10. Therefore, in the present embodiment, the maximum value of the size SPx corresponds to the size SLx that is determined by the disposed number of the concentrating lenses 11 in the row direction Dx of the concentrating lens array 10 (disposed number×size SLx), i.e., the sizes SLx of the five disposed concentrating lenses 11 (5×size SLx).

Also, the size Spy of the heat diffusion plate 30 in the column direction Dy is smaller than the size SLy of each concentrating lens 11 in the column direction Dy. Since the size SPy of the heat diffusion plate 30 is formed smaller than the size SLy of the concentrating lens 11, a plurality of heat diffusion plates 30 are disposed independently from each other in the column direction Dy of the concentrating lens array 10.

As described above, the concentrator photovoltaic device 1 includes the concentrating lenses 11 concentrating sunlight Ls, the solar cell elements 20 photoelectrically convert the sunlight Ls concentrated by the concentrating lenses 11 and the mounting substrates 21 on which the respective solar cell elements 20 are mounted. Also, the concentrator photovoltaic device 1 includes the concentrating lens array 10 that is configured by the concentrating lenses 11 respectively arranged in the row direction Dx and the column direction Dy, and the heat diffusion plate 30 on which the mounting substrates 21 are mounted and that diffuses heat from the mounting substrates 21. The heat diffusion plate 30 is disposed facing the concentrating lenses 11 disposed in the row direction Dx. The size SPx of the heat diffusion plate 30 in the row direction Dx is two or more times as large as the size SLx of the concentrating lens 11 in the row direction Dx. The size SPy of the heat diffusion plate 30 in the column direction Dy is smaller than the size SLy of the concentrating lens 11 in the column direction Dy.

Since the concentrator photovoltaic device 1 includes the heat diffusion plate 30 on which the solar cell elements 20 (and the mounting substrates 21) are mounted, even if intensities of the concentrated sunlight Ls incident on the solar cell elements 20 (mounting substrates 21) differ from each other, which results in difference in heated states of the solar cell elements 20, heat is dissipated from the heat diffusion plate 30 so as to equalize the heated states of the respective solar cell elements 20.

Thus, in the concentrator photovoltaic device 1, heat dissipation properties are improved to effectively suppress the temperature rise of the solar cell elements 20, thus output deterioration by the rise in temperature of the solar cell elements 20 is suppressed to obtain a high photoelectric conversion efficiency. Furthermore, in the concentrator photovoltaic device 1, since the mounting substrates 21 are mounted on the same heat diffusion plate 30, the mounting substrates 21 are mounted simply, the productivity is improved and the cost can be reduced.

Also, the concentrator photovoltaic device 1 includes the heat diffusion plate 30 on which the solar cell elements 20 (and the mounting substrates 21) are mounted, heat dissipation paths from the respective solar cell elements 20 to the outside of the concentrator photovoltaic device 1 can be simplified and equalized. Thus, electrical power generation properties of the solar cell elements 20 can be equalized.

The minimum value of the size SPy of the heat diffusion plate 30 in the column direction Dy may be set to approximately the value of which the mounting substrate 21 is not beyond the size of the heat diffusion plate 30 in the column direction Dy. That is, the size SPy of the heat diffusion plate 30 in the column direction Dy may be equal to or more than the size of the mounting substrate 21 in the column direction Dy. Thus, the mounting substrates 21 can be mounted accurately on the heat diffusion plate 30 in the row direction Dx. Also, the minimum value of the size SPy can be determined taking into consideration a margin to prevent an adhesive that forms an adhering-fixing portion 28 (see FIG. 2A) from being beyond the heat diffusion plate 30, and can be set to a value resulting from addition, for example, of a margin of several mm to the size of the mounting substrate 21 in the column direction Dy.

The concentrator photovoltaic device 1 includes the housing frame 40 (bottom portion 40b) on which the heat diffusion plates 30 are mounted. Therefore, in the concentrator photovoltaic device 1, the heat diffusion plate 30 on which the plurality of mounting substrates 21 are mounted makes contact with the housing frame 40 (the bottom portion 40b), thus, when heat from the heat diffusion plate 30 (the mounting substrates 21) is dissipated to the outside of the concentrator photovoltaic device 1, a heat dissipation area (a surface area of the housing frame 40) can be enlarged. Therefore, heat of the heat diffusion plate 30 (the mounting substrates 21) can be effectively dissipated to the outside of the concentrator photovoltaic device 1 so that the heat dissipation of the concentrator photovoltaic device 1 can be further improved.

In the concentrator photovoltaic device 1, the concentrating lens array 10 is positioned relative to the housing frame 40 (the wall portion 40w), the heat diffusion plate 30 is positioned relative to the housing frame 40 (the bottom portion 40b), thereby the concentrating lens array 10 and the heat diffusion plate 30 can be positioned to each other. That is, the heat diffusion plate 30 is positioned at (mounted on) the bottom portion 40b of the housing frame 40, and the concentrating lens array 10 is positioned at (mounted on) the flange portion 40g of the housing frame 40. Furthermore, the bottom portion 40b and the wall portion 40w are positioned to each other with high accuracy set in advance.

The heat diffusion plate 30 includes plate mounting holes 30h that serve as fastening holes when the heat diffusion plate 30 is fastened to the bottom portion 40b (the housing frame 40). Also, in the bottom portion 40b, plate fixing holes 40s to position and fix the respective plate mounting holes 30h are formed in advance. Therefore, the plate mounting holes 30h are positioned at the respective plate fixing holes 40s of the bottom portion 40b, thus the heat diffusion plate 30 is positioned at the housing frame 40 (the bottom portion 40b) with high accuracy.

That is, the heat diffusion plate 30 and the bottom portion 40b (the housing frame 40) are fastened via the plate mounting holes 30h and the plate fixing holes 40s with fastening members 41 such as bolts-nuts, and rivets (see FIG. 2A). At least two plate mounting holes 30h will be sufficient to position the heat diffusion plate 30.

On the heat diffusion plate 30 are mounted in advance the mounting substrates 21 on which the respective solar cell elements 20 are mounted. Also, the heat diffusion plate 30 has a sufficiently large area in comparison with each mounting substrate 21, thus workability for fastening the heat diffusion plate 30 to the bottom portion 40b can be improved.

It is not necessary to prepare the fastening members 41 for the mounting substrates 21, but only necessary to prepare for the heat diffusion plates 30. Thus, the number of the fastening members 41 necessary for fastening can be considerably reduced. As the mounting substrates 21 are mounted in advance on the heat diffusion plates 30, the solar cell elements 20 (the mounting substrates 21) can be mounted in a simple manner on the housing frame 40.

For producing the solar cell element 20, for example, a GaAs based compound semiconductor is used to form a p-n junction, electrodes (a substrate electrode and a front surface electrode) and the like on a wafer by a known semiconductor processing. Thus, the wafer is processed to produce the solar cell element 20 in a form of a chip having 1-10 mm square. In the present embodiment, the size of each solar cell element 20 is 5 mm square.

The heat diffusion plate 30 is preferably made of copper, copper alloy, aluminum, aluminum alloy, or the like, which have a high heat conductivity. In the present embodiment, the heat diffusion plate 30 is formed by A1050P (JIS standard) that is an aluminum plate material having a purity of 99.5% or more. The thickness of the heat diffusion plate 30 should be optimized based on an amount of heat generation of the solar cell elements 20, and preferably is about 0.5-5 mm, for example. In the present embodiment, the heat diffusion plate 30 has a thickness of 2 mm.

As described above, the size of the heat diffusion plate 30 is determined according to the size SLx of each concentrating lens 11 in the row direction Dx and the size SLy of each concentrating lens 11 in the column direction Dy. In the present embodiment, the size SPx of the heat diffusion plate 30 in the row direction Dx is 850 mm (5×size SLx 170 mm), and the size SPy of the heat diffusion plate 30 in the column direction Dy is 75 mm (size SLy 170 mm×about 0.44).

The mounting substrates 21, on which the respective solar cell elements 20 are mounted, are mounted on the heat diffusion plate 30 that has a good heat conductivity, and the heat diffusion plates 30 are mounted on the housing frame 40. Thus, heat brought to the solar cell elements 20 by the concentrating function of the concentrating lenses 11 transfers to the heat diffusion plate 30 via the mounting substrate 21. The heat is conducted to the housing frame 40 while appropriately diffused in the heat diffusion plate 30, thus the heat can be dissipated from the housing frame 40 to the air.

Therefore, while the costs of materials such as the heat diffusion plate 30, and the housing frame 40 are reduced, the temperature rise of the solar cell element 20 can be effectively suppressed. Thus, output deterioration by the rise in temperature of the solar cell element 20 is suppressed to obtain a high photoelectric conversion efficiency.

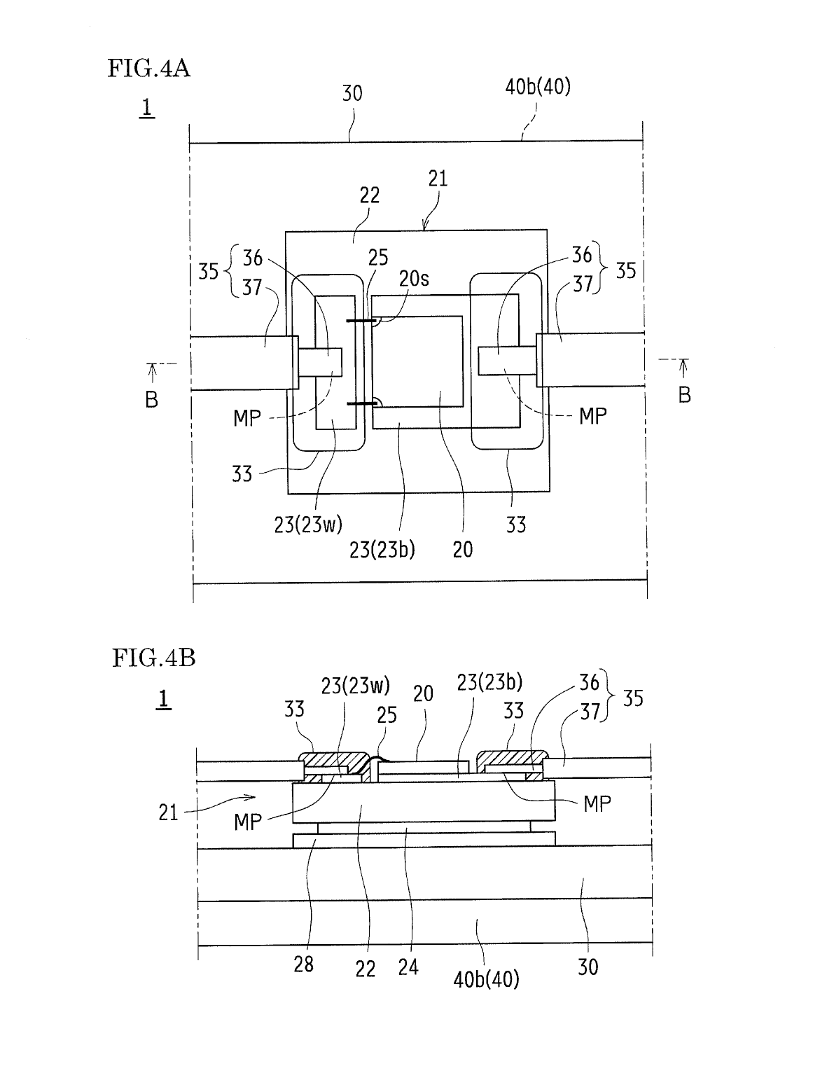

Also, in the present embodiment, the size SPx of the heat diffusion plate 30 in the row direction Dx (length in the longitudinal direction) is 850 mm, and the size SPy of the heat diffusion plate 30 in the column direction Dy (length in the short direction) is 75 mm. Thus, the solar cell elements 20 and the mounting substrates 21 of one row and a plurality of columns (in the present embodiment, one row and five columns) are disposed. Therefore, while the heat diffusion plate 30 is conveyed in the row direction Dx without movement in the column direction Dy, a manufacturing process can be performed such as fixing of the mounting substrate 21 to the heat diffusion plate 30, welding of the connecting wiring 35 between the respective mounting substrates 21, and sealing of live parts with a resin sealing portion 33 (see FIGS. 4A and 4B). Thus, high productivity and cost reduction can be obtained.

FIG. 2A is a cross-sectional view showing an overlapped state of components taken from arrows A-A in FIG. 1B. A hatching to indicate the cross-section is omitted for visibility of the drawing.

The mounting substrate 21 is fixed to the heat diffusion plate 30 via the adhering-fixing portion 28. That is, the concentrator photovoltaic device 1 preferably includes the adhering-fixing portion 28 that adheres and fixes the mounting substrate 21 to the heat diffusion plate 30.

Thus, in the concentrator photovoltaic device 1, the mounting substrate 21 is fixed to the heat diffusion plate 30 via the adhering-fixing portion 28 (an adhesive) that has an area substantially equal to the mounting substrate 21. It is not necessary to form, on the mounting substrate 21, a region (for example, a region where the fastening members are disposed) for mechanically fixing the mounting substrate 21 to the heat diffusion plate 30. Thus, the mounting substrate 21 can be made small. Furthermore, heat from the mounting substrate 21 can be smoothly and effectively dissipated to the heat diffusion plate 30 via the adhering-fixing portion 28.

In the present embodiment, the adhering-fixing portion 28 is formed by silicone resin containing heat conductive filler. The adhering-fixing portion 28 has a thickness of about 50 μm and a heat conductivity of 2.5 W/m·K. The more the heat conductivity becomes high, the more the heat dissipation function becomes improved. However, the more the heat conductivity becomes high, the more the cost generally becomes high due to expensiveness of contained filler.

It is necessary to select an adhesive having an optimal heat conductivity as a constituent material of the adhering-fixing portion 28, taking into consideration the thickness of the adhering-fixing portion 28, an amount of heat generation of the solar cell element 20, and the like. The adhering-fixing portion 28 suitable for the concentrator photovoltaic device 1 preferably has a heat conductivity of at least 1 W/m·K in consideration of heat dissipation.

That is, it is preferable that the adhering-fixing portion 28 is formed by a synthetic resin material having a heat conductivity of 1 W/m·K or more. Therefore, in the concentrator photovoltaic device 1, the mounting substrate 21 is adhered to the heat diffusion plate 30 via the adhering-fixing portion 28 having a high heat conductivity. Thus, heat brought to the solar cell element 20 (the mounting substrate 21) can be efficiently conducted to the heat diffusion plate 30.

Also, it is preferable that the adhering-fixing portion 28 relaxes the stress due to the difference between the respective coefficients of linear expansion of the heat diffusion plate 30 and the mounting substrate 21. For this reason, the adhering-fixing portion 28 preferably has a low hardness and is thick to the extent that it does not affect heat dissipation. In the present embodiment, since the silicone resin is applied to the adhering-fixing portion 28, these objectives can be achieved. Also, a region where the adhering-fixing portion 28 is formed is limited to a region corresponding to the mounting substrate 21 (a rear surface region of the mounting substrate 21) so that the mounting substrate 21 is fixed to the heat diffusion plate 30. Thus, it is not necessary to use an unnecessary amount of synthetic resin, thereby the cost can be effectively reduced.

Between the solar cell elements 20 (the mounting substrates 21), the connecting wiring 35 is disposed to connect the mounting substrates 21 to each other. The connecting wiring 35 includes a connecting conductor 36 that connects the mounting substrates 21 to each other and an insulating coating material 37 that coats the connecting conductor 36. The connecting wiring 35 (the connecting conductor 36) is disposed in a form of a bar (a beam) between the mounting substrates 21 so as to make space relative to the environment.

That is, in the concentrator photovoltaic device 1, the connecting conductor 36 is preferably disposed in a form of a beam between the conductors 23. In the concentrator photovoltaic device 1, since the connecting conductor 36 coated by the insulating coating material 37 is disposed in a form of a beam, the connecting conductor 36 can be reliably prevented from making contact with another conductive region. Thus, connection reliability between the solar cell elements 20 can be further improved.

The housing frame 40 includes the bottom portion 40b. On the both sides of the bottom portion 40b, the respective wall portions 40w are formed so as to extend in the perpendicular direction. On the top surfaces of the wall portions 40w, the flange portions 40g are formed. On the flange portions 40g, the concentrating lens array 10 is disposed so that the concentrating lens 11 is irradiated with sunlight Ls.

On the bottom portion 40b, the plurality of heat diffusion plates 30 (see FIG. 1B) are fastened. The solar cell element 20 (the mounting substrate 21) mounted on the heat diffusion plate 30 is positioned at the concentrating lens 11. The solar cell element 20 is irradiated with the sunlight Ls concentrated by the concentrating lens 11. The mounting substrate 21 on which the solar cell element 20 is mounted is fixed (adhered) to the heat diffusion plate 30 via the adhering-fixing portion 28.

Along the row direction Dx, five concentrating lenses 11 are disposed (see FIG. 1A), and five solar cell elements 20 (mounting substrates 21) are disposed corresponding to the respective concentrating lenses 11. Also, one heat diffusion plate 30 is disposed corresponding to the whole of five concentrating lenses 11. Thus, the concentrating lens array 10 and the heat diffusion plate 30 are disposed at respective locations so as to face each other.

The housing frame 40 is made by assembling highly corrosion-resistant steel sheets (for example, highly corrosion-resistant steel sheets that has high corrosion resistance and has a ternary eutectic structure made of zinc, aluminum and magnesium) such as a hot-dip galvanized steel sheet, by fastening such highly corrosion-resistant steel sheets using the fastening members such as rivets so as to make a box structure that is opened at one face irradiated with the sunlight Ls. In the present embodiment, for the housing frame 40, steel sheets that have a thickness of 0.8 mm are used in consideration of their strength.

In the bottom portion 40b of the housing frame 40, the plate fixing holes 40s are provided for positioning and fixing the heat diffusion plates 30. The plate mounting hole 30h of the heat diffusion plate 30 and the plate fixing hole 40s of the housing frame 40 (bottom portion 40b) are positioned to each other, and fastened to each other using the fastening member 41 (for example, a rivet made of aluminum). Thus, the heat diffusion plate 30 is fastened to the housing frame 40 by the fastening members 41 with high accuracy.

The plate mounting hole 30h of the heat diffusion plate 30 is used in common as a positioning reference hole (not shown) of a jig (not shown) when the mounting substrates 21 (the solar cell element 20) are installed by the jig (not shown). Therefore, by matching and fastening to each other the plate mounting hole 30h of the heat diffusion plate 30 and the plate fixing hole 40s of the housing frame 40 (the bottom portion 40b), the positions of the respective mounting substrates 21 and the housing frame 40 are accurately positioned to each other, and in addition, the mounting substrates 21 (the solar cell elements 20) and the concentrating lenses 11 (the concentrating lens array 10) are accurately positioned to each other.

FIG. 2B is an enlarged cross-sectional view showing the disposed state of the solar cell element 20 shown in FIG. 2A. A hatching to indicate the cross-section is omitted for visibility of the drawing.

FIG. 3 is a plain view showing a connecting state of connecting wirings 35 relative to the solar cell element 20 shown in FIG. 2B. The resin sealing portion 33 (see FIGS. 4A and 4B) is omitted for visibility of the drawing.

In the concentrator photovoltaic device 1 according to the present embodiment, the mounting substrates 21 include the respective conductors 23 (the respective first conductors 23b and the respective second conductors 23w. Such first conductors 23b and second conductors 23w will be further described with reference to FIGS. 4A and 4B) to which the respective solar cell elements 20 are connected and respective insulators 22 on which the respective conductors 23 are disposed. That is, in the concentrator photovoltaic device 1, the solar cell elements 20 are mounted on the respective mounting substrates 21 (the first conductors 23b mounted on the respective insulators 22), thus, the solar cell elements 20 are mounted on the respective stable-shaped conductors 23 (respective first conductors 23b), and the conductors 23 are insulated from the heat diffusion plate 30 via the respective insulators 22. Thus, the solar cell elements 20 are reliably insulated from the heat diffusion plate 30. And, when the solar cell elements 20 are disposed on the heat diffusion plate 30, high insulation properties can be ensured between the solar cell elements 20.

The conductors 23 include the respective first conductors 23b (conductors 23) and the respective second conductors 23w (conductors 23). The respective solar cell elements 20 are mounted on, and rear surface electrodes (not shown) of the respective solar cell elements 20 are connected to, the first conductors 23b (conductors 23). To the second conductors 23w (conductors 23), the front surface electrodes (not shown) of the respective solar cell elements 20 are connected via respective connecting members 25 (see FIG. 4A).

The insulator 22 is formed by molding ceramic material such as AlN (aluminum nitride), Al₂O₃ (alumina), Si₃N₄ (silicone nitride) and the like into a plate shape. The insulator 22 is a member to electrically insulate the conductor 23 that serves as a circuit through which current passes from the heat diffusion plate 30 that serves as a ground potential. Generally, the ceramic material has high weatherability and reliability, and does not decrease significantly insulation resistance during high temperature compared to synthetic resin and the like. The insulator 22 is preferably made of AlN. Among the ceramic materials, AlN has a high heat conductivity compared to other ceramic materials and an insulating synthetic resin material. Therefore, by using AlN as the constituent material of the insulator 22, the insulation and the heat dissipation are further improved, thus a reliable concentrator photovoltaic device 1 can be configured.

Preferably, the volume resistivity of the insulator 22 is 10¹² Ω·cm or more. With this configuration, insulation of the mounting substrate 21 is reliably realized, thus high insulation between the solar cell elements 20 can be ensured. Furthermore, the insulator 22 is preferably formed by a ceramic material. With this configuration, insulation of the mounting substrate 21 can be easily realized. Also, the ceramic material is, preferably, aluminum nitride. With this configuration, the high insulation and the high heat conductivity are ensured. Furthermore, the conductor 23 can be easily formed by aluminum (or aluminum alloy).

That is, when aluminum (or aluminum alloy) is used for the connecting wiring 35 and the heat diffusion plate 30, the conductor 23 can be formed by aluminum (or aluminum alloy). Thus, consistency of the heat conductivity (the heat conductivity ratio) of the entire device is ensured, and the heat (temperature) reliability (the heat properties or the temperature properties) can be improved.

It is possible to use synthetic resin such as a resin film containing conductive filler for the insulator 22 to electrically insulate the conductor 23 from the heat diffusion plate 30. With this configuration, however, under the condition in which the outside temperature is high and sun beam is intense (for example, a desert near the equator), the temperature rise of the synthetic resin results in decrease of the insulation resistance of the synthetic resin, thereby reliability may be degraded.

In the concentrator photovoltaic device 1 according to the present embodiment, the insulator 22 is disposed between the conductor 23 and the heat diffusion plate 30, thus the high insulation and reliability can be obtained. Furthermore, since the insulator 22 is formed by the ceramic material, it is possible to prevent the insulation resistance from decreasing under high temperature in comparison with the case in which insulating resin is used for the insulator 22 for insulation. Thus, when the plurality of concentrator photovoltaic devices 1 are disposed, the high insulation between the solar cell elements 20 can be ensured, thereby reliability can be improved.

The conductor 23 is formed on the front surface of the insulator 22. On the rear surface of the insulator 22 (reverse surface of the surface on which the conductor 23 is formed), a rear surface conductor 24 is formed. The rear surface conductor 24 (the insulator 22) is adhered and fixed to the heat diffusion plate 30 via the adhering-fixing portion 28. That is, the mounting substrate 21 is fixed to the heat diffusion plate 30 via the adhering-fixing portion 28. Therefore, the solar cell element 20 (the mounting substrate 21) is fixed to the heat diffusion plate 30 via the adhering-fixing portion 28, and positioned at an optical axis Lax from the concentrating lens 11 to the solar cell element 20.

The conductor 23 (the first conductor 23b and the second conductor 23w) and the rear surface conductor 24 are adhered to the insulator 22 by an appropriate adhesive such as a brazing material. The conductor 23 is formed by a material such as copper, copper alloy, aluminum and aluminum alloy. In the present embodiment, aluminum having a purity of 99.9% or more is used for the conductor 23 and the rear surface conductor 24.

When the insulator 22 and the conductor 23 are adhered to each other by the brazing material and the like, warp may occur because the coefficient of linear expansion is different between the insulator 22 and the conductor 23. For this reason, to the reverse surface (the rear surface of the insulator 22) of the conductor 23 formed on the surface of the insulator 22, the rear surface conductor 24 is adhered by the brazing material and the like. The rear surface conductor 24 is made of the same metal as the conductor 23, and the thickness of the rear surface conductor 24 is adjusted according to the amount of warp. Thus, the warp of insulator 22 can be prevented.

On the surface of the first conductor 23b on which the solar cell element 20 is mounted, Ni—P plating (not shown) is performed, and the Ni—P plating and the rear surface electrode (the substrate electrode, not shown) of the solar cell element 20 are soldered in a reflow furnace and the like. Thus, the solar cell element 20 (the solar cell element chip) is mounted on (adhered to) the mounting substrate 21, and the rear surface electrode of the solar cell element 20 is connected (brought into electric continuity) to the first conductor 23b.

The electrodes (the front surface electrode and the rear surface electrode) of the solar cell element 20 can be arranged in any manner. The conductor 23 is laid out according to the configuration of the electrodes of the solar cell element 20. The conductor 23 is formed on the surface of the insulator 22 as a flat conductor pattern having a shape of a thin plate (or a thick film).

On the conductor 23, the connecting wiring 35 is disposed so as to connect the adjacent mounting substrates 21 (the solar cell elements 20) to each other. The connecting wiring 35 includes the connecting conductor 36 to connect the conductors 23 and the insulating coating material 37 that coats the connecting conductor 36 so that the connecting conductor 36 is insulated from the environment. Also, the connecting wiring 35 is disposed in a form of a beam between the mounting substrates 21 (the solar cell elements 20) so as to make a space (a gap) relative to the heat diffusion plate 30.

That is, the connecting wiring 35 includes the connecting conductor 36 that connects the adjacent mounting substrates 21 to each other and the insulating coating material 37 that coats the both surfaces (the surrounding area) of the connecting conductor 36. The insulating coating material 37 is laminated on the connecting conductor 36. Therefore, at the tip portion of the connecting wiring 35, the connecting conductor 36 is exposed without coated by the insulating coating material 37 and protrudes from the insulating coating material 37.

The protruded connecting portion (the connecting conductor 36) of the connecting wiring 35 and the conductor 23 of the mounting substrate 21 are welded (adhered), for example, by ultrasonic welding, to be connected (wired) at a welding portion MP (FIG. 3). The connecting conductor 36 of the connecting wiring 35 and the conductor 23 of the mounting substrate 21 are welded by ultrasonic welding, thus a connecting region on the conductor 23 relative to the connecting conductor 36 can be reduced in comparison with wiring of a lead wire to the mounting substrate 21 using solder and soldering iron, which is known as a conventional art. In the result, the mounting substrate 21 (the insulator 22) can be made small. Therefore, the costs for the mounting substrate 21 can be reduced. Apart from the ultrasonic welding, it is also possible to use laser welding, spot welding and the like.

As described above, in the concentrator photovoltaic device 1, it is preferable that the connecting conductor 36 is connected to the conductor 23 by welding. Therefore, in the concentrator photovoltaic device 1, the connecting conductor 36 is connected to the conductor 23 by welding. Thus, it is possible to enhance connection strength and improve reliability compared to the solder connection. Also, in contrast to the solder connection, it is possible to reduce the connecting region (space saving), thus the mounting substrate 21 can be reliably made small.

Also, the concentrator photovoltaic device 1 preferably includes the connecting wiring 35 that connects the conductor 23 of one mounting substrate 21 to the conductor 23 of the adjacent mounting substrate 21. The connecting wiring 35 preferably includes the connecting conductor 36 that connects the conductors 23 to each other and the insulating coating material 37 that coats the connecting conductor 36.

Therefore, in the concentrator photovoltaic device 1, the conductors 23 of the adjacent mounting substrates 21 are connected to each other via the connecting conductor 36 that is coated by the insulating coating material 37. Thus, it is possible to prevent the connecting conductor 36 from making contact with another conductive region, thereby improving connection reliability.

FIG. 4A is an enlarged plain view showing a main configuration of the concentrator photovoltaic device 1 according to the embodiment of the present invention.

FIG. 4B is a cross-sectional view showing a cross-section taken from arrows B-B in FIG. 4A. Hatchings are made only on the resin sealing portions 33.

At end portions of the front surfaces (surfaces facing the concentrating lenses 11) of the solar cell elements 20, front surface electrodes 20s (collecting electrodes) are formed. The front surface electrodes 20s are connected to the respective second conductors 23w via the respective connecting members 25.

That is, the conductors 23 are respectively made up of the respective first conductors 23b on which the respective solar cell elements 20 are mounted and the respective second conductors 23w that are disposed separated apart from the respective first conductors 23b. The second conductors 23w and the front surface electrodes 20s that are formed on the front surfaces of the respective solar cell elements 20 are preferably connected by the respective connecting members 25 formed by a metal material. With this configuration, in the concentrator photovoltaic device 1, the front surface electrode 20s of the solar cell element 20 and the second conductor 23w can be easily connected.

The connecting member 25 is formed by the metal material. Thus, the connecting member 25 has a shape of a metal wire or a metal foil so as to connect (wire bonding) easily the front surface electrode 20s to the second conductor 23w. As the metal material, it is preferable to use aluminum (or aluminum alloy) and the like.

Also, when the heat diffusion plate 30, the connecting conductor 36 and the conductor 23 are formed by aluminum (or aluminum alloy), the connecting member 25 is preferably formed by aluminum (or aluminum alloy).

That is, the conductor 23 is connected to the solar cell element 20 (for example, by ultrasonic welding) using the same metal (the connecting member 25) as the conductor 23 to obtain high connection strength. Also, the coefficient of linear expansion of the conductor 23 is equal to that of the connecting member 25, it is possible to prevent occurrence of defect such as cut of the connecting member 25 (wire breaking) due to temperature cycle.

On the rear surface of the solar cell element 20 (the surface that is adhered to the first conductor 23b), the rear surface electrode (not shown) is formed. The rear surface electrode is adhered (brought into electric continuity) to the first conductor 23b. Therefore, electrical power generated by photoelectric conversion of sunlight Ls by the solar cell element 20 is output from the connecting wiring 35 via the first conductor 23b connected to the rear surface electrode and the second conductor 23w connected to the front surface electrode. In the concentrator photovoltaic device 1, the connecting wiring 35 is appropriately wired (series connection/parallel connection) to obtain a desired electrical power generation system (a photovoltaic device).

The connecting conductor 36 of the connecting wiring 35 is formed, for example, by copper, copper alloy, aluminum, aluminum alloy, or the like. In the present embodiment, the connecting conductor 36 is formed by A1050P (JIS standard) that is an aluminum plate material having a purity of 99.5% or more. The size of the connecting conductor 36 is determined in consideration of an amount of current of an electrical power generation system (a photovoltaic device) and costs of a wiring material that constitutes the connecting wiring 35. In the present embodiment, the size of the connecting conductor 36 is 6 mm width×160 mm length×200 μm thickness. Since the connecting conductor 36 has the plate thickness of 200 μm, it has hardness sufficient to maintain its shape, thus, it is possible to connect to each other the adjacent mounting substrates 21 (conductors 23) due to its shape of bar (beam, plate).

The material of the insulating coating material 37 of the connecting wiring 35 is determined in consideration of dielectric strength voltage and reliability. The materials of insulating coating material 37 include PET (polyethylene terephthalate) resin, PEN (polyethylene naphthalate) resin, PI (polyimide) resin and the like. The acceptable value of the dielectric strength voltage of the connecting wiring 35 is different depending on specifications of concentrator photovoltaic modules. Thus, for example, the material and the thickness of the insulating coating material 37 is determined so that the connecting wiring 35 withstands a voltage of 3000V without generating dielectric breakdown (the dielectric strength voltage of 3000V or more). In the present embodiment, PEN resin of 50 μm is used for the insulating coating material 37.

As a laminating material (adhering material) for forming the connecting wiring 35 by adhering and integrating the connecting conductor 36 and the insulating coating material 37, an appropriate material is selected in consideration of adhesion compatibility with the connecting conductor 36 and the insulating coating material 37, relaxation of stress generated by the difference in the coefficient of linear expansion between the connecting conductor 36 and the insulating coating material 37, and adhesion reliability. In the present embodiment, an epoxy adhesive is used as an adhesive (an adhering material) between the connecting conductor 36 and the insulating coating material 37.

It is preferable that the conductor 23 (the first conductor 23b and the second conductor 23w) of the mounting substrate 21 and the connecting conductor 36 of the connecting wiring 35 are formed by the same metal material. Thus, in the concentrator photovoltaic device 1, since the conductor 23 and the connecting conductor 36 are formed by the same metal material, the connection becomes easy. Also, it is possible that the welding having a connection strength higher than those of the different metals can be performed, thereby obtaining further higher reliability. Furthermore, properties of both members (the conductor 23 and the connecting conductor 36) to heat (such as expansion and contraction due to heat expansion properties) conform, thus heat resistance is improved.

When the conductor 23 and the connecting conductor 36 are formed by the same metal material, it is possible that the conductor 23 and the connecting conductor 36 are more firmly welded in comparison with the case in which the conductor 23 and the connecting conductor 36 are formed by the different metal materials. Thus, reliability of the welding portion MP is improved.

It is preferable that when the conductor 23 and the connecting conductor 36 are formed by the same metal material, such a metal material is aluminum or aluminum alloy. Thus, when the conductor 23 and the connecting conductor 36 are formed by aluminum or aluminum alloy, weight and cost saving of the concentrator photovoltaic device 1 becomes possible in comparison with the case in which copper or copper alloy is used for the conductor 23 and the connecting conductor 36. Furthermore, because of high corrosion resistance, reliability is improved.

Also, by using aluminum or aluminum alloy for the conductor 23, heat of the solar cell element 20 can be rapidly diffused and conducted to the conductor 23. Also, by using aluminum or aluminum alloy for the conductor 23, it is possible to cut cost significantly in comparison with the case in which copper or copper alloy is used for the connecting conductor 36 of the connecting wiring 35 and the conductor 23 of the mounting substrate 21. By using aluminum or aluminum alloy for the conductor 23, it is possible to decrease electrical resistance at the connecting conductor 36 and electrical resistance at the welding portion MP of the connecting conductor 36 relative to the conductor 23, thus electrical power loss generated in the concentrator photovoltaic device 1 (the mounting substrate 21 and the connecting wiring 35) can be reduced.

It is preferable that the heat diffusion plate 30 and the connecting conductor 36 are formed by the same metal material. Thus, in the concentrator photovoltaic device 1, since heat diffusion plate 30 and the connecting conductor 36 are formed by the same metal material, when the heat diffusion plate 30 and the connecting wiring 35 (the connecting conductor 36) become high temperature by the light concentrating function, or when the device is installed in an environment where there is large variation in the outside temperature (for example, in a desert and the like), difference in changes due to temperature change (expansion and contraction by the heat expansion properties and the like) of the heat diffusion plate 30 and the connecting conductor 36, which are remarkably affected by the coefficient of linear expansion, is suppressed. Thus, connection reliability can be improved.

Specifically, when the heat diffusion plate 30 and the connecting conductor 36 are heated affected by heat generation of the solar cell element 20 by the light concentrating function of the concentrating lens 11, and when there is large variation in the outside temperature, the heat diffusion plate 30 and the connecting wiring 35 formed by the same metal have the same coefficient of linear expansion, that is, the connecting wiring 35 (connecting conductor 36) and the heat diffusion plate 30 expand (or contracted) by substantially the same degree.

For example, when the heat diffusion plate 30 expands by a temperature rise, the interval of the adjacent mounting substrates 21 expands. Thus, the connecting conductor 36 is pulled by the adjacent mounting substrates 21. However, since the heat diffusion plate 30 and the connecting conductor 36 are formed by the same metal, they expand by substantially the same degree, and pulling stress is relaxed. If a metal having lower coefficient of linear expansion than that of the heat diffusion plate 30 is used for the connecting conductor 36, the connecting conductor 36 is pulled by the mounting substrate 21 fixed to the heat diffusion plate 30, then stress is generated at the welding portion MP that has the lowest strength. At worst, break occurs. In the present embodiment, the same metal is used for the connecting conductor 36 and the heat diffusion plate 30, reliability of welding portion MP of the mounting substrate 21 and the connecting conductor 36 can be improved.

It is preferable that when the heat diffusion plate 30 and the connecting conductor 36 are formed by the same metal material, such a metal material is aluminum or aluminum alloy. Thus, when the heat diffusion plate 30 and the connecting conductor 36 are formed by aluminum or aluminum alloy, weight and cost saving of the concentrator photovoltaic device 1 becomes possible in comparison with the case in which copper or copper alloy is used. Furthermore, because the metal material of the heat diffusion plate 30 and the connecting conductor 36 have high corrosion resistance, reliability is improved.

Furthermore, the conductor 23, the heat diffusion plate 30 and the connecting conductor 36 are preferably formed by the same metal material. That is, in the concentrator photovoltaic device 1, it is possible to relax stress added to the connection portion (welding portion MP) of the conductor 23 and the connecting conductor 36 by expansion of the heat diffusion plate 30 and the expansion of the connecting conductor 36. Thus, connection reliability of the conductor 23 and the connecting conductor 36 can be improved. By using the same metal material to form the conductor 23, the connecting conductor 36 and the heat diffusion plate 30, the connection reliability can be further improved. When the conductor 23, the heat diffusion plate 30 and the connecting conductor 36 are formed by the same metal material, such a metal material is preferably aluminum or aluminum alloy, as described above.

In the concentrator photovoltaic device 1, the welding portion MP that is formed by welding of the conductor 23 (the first conductor 23b and the second conductor 23w) of the mounting substrate 21 and the connecting conductor 36 (the connecting wiring 35), and surroundings of the welding portion MP become live parts. Thus, the welding portion MP and its surroundings are insulated and sealed by the resin sealing portion 33. That is, the concentrator photovoltaic device 1 includes the resin sealing portion 33 formed around the welding portion MP. The resin sealing portion 33 is formed so as to cover the welding portion MP that is formed on the conductor 23 (the first conductor 23b and the second conductor 23w) and the connecting conductor 36 (protruding portion at the tip portion of the connecting wiring 35) connected to the conductor 23 via the welding portion MP. The resin sealing portion 33 is formed outside the solar cell element 20 so as to not shield sunlight Ls.

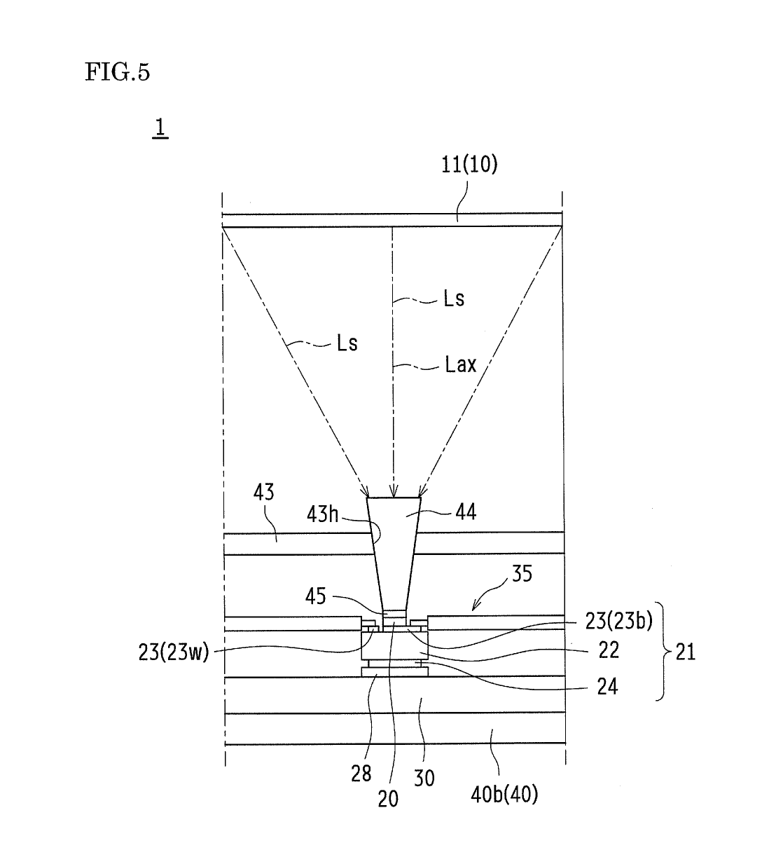

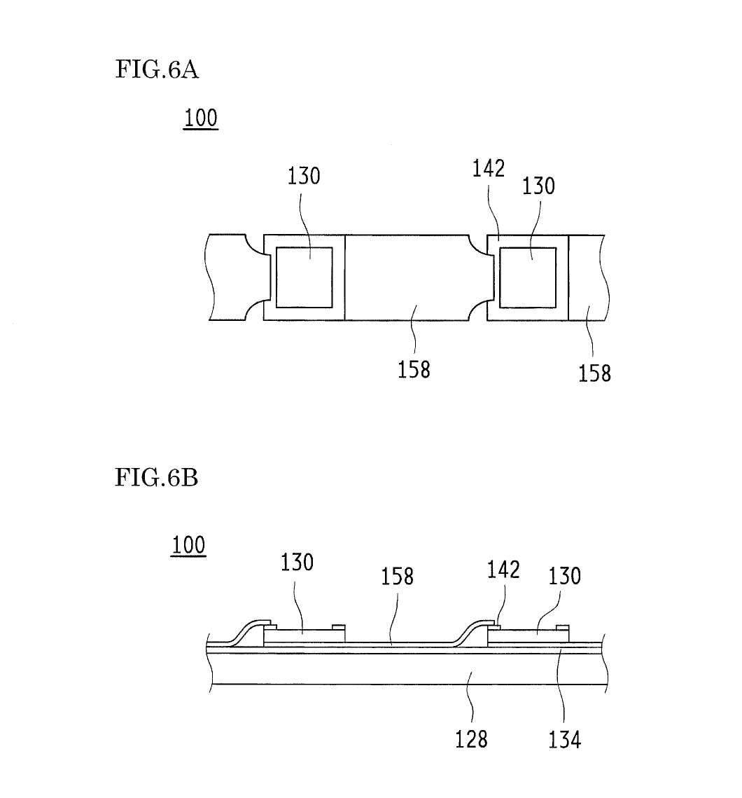

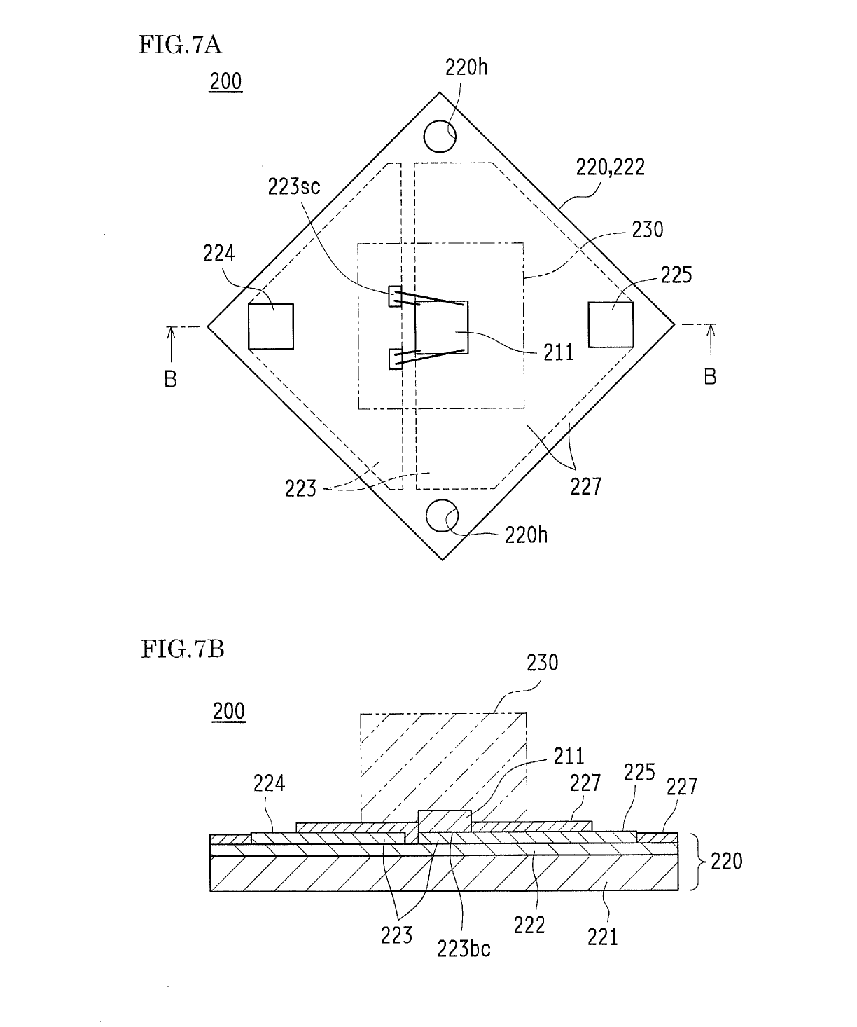

A synthetic resin material that has the most suitable material and viscosity is selected as the resin sealing portion 33 in consideration of coating ability, reliability and the like relative to the welding portion MP. In the present embodiment, silicone resin of 5 Pa·s viscosity (absolute viscosity) is applied to live parts (the welding portion MP and the connecting conductor 36) by a dispenser, thus the resin sealing portion 33 is formed. The silicone resin is, for example, colorless and transparent, or white. In FIG. 4A, the resin sealing portion 33 is transparent and the connecting conductor 36 can be viewed. Furthermore, the resin sealing portion 33 can be prevented from deviation in light concentration by an appropriate light shielding plate 43 (see FIG. 5).

With reference to FIG. 5, description will be given on a variation example of the concentrator photovoltaic device 1 according to the present embodiment. As the basic configuration of the concentrator photovoltaic device according to the variation example is similar to the concentrator photovoltaic device 1 as shown in FIG. 2, different points will be mainly described citing, as necessary, the reference numerals.

FIG. 5 is an enlarged cross-sectional view showing a variation example of the concentrator photovoltaic device 1 according to the embodiment of the present invention in a state similar to FIG. 2B. Similarly to FIG. 2B, the hatching is omitted.

On the surface of the solar cell element 20 mounted on the first conductor 23b, a pillar-shaped light guide portion 44 is disposed via a attaching portion 45.

An incident side (a top surface) of the pillar-shaped light guide portion 44 on which sunlight Ls concentrated by the concentrating lens 11 is incident is formed so as to be disposed in the range larger in some degree than the irradiation range (the light concentration spot: the light concentration region) of the concentrated sunlight Ls. Thus, it is possible to eliminate influence caused by deviation in light concentration due to position deviation and angle deviation of light concentration by the concentrating lens 11. That is, the top surface of the pillar-shaped light guide portion 44 is formed so as to cover the range of the deviation in light concentration.

Also, an output side (a bottom surface) of the pillar-shaped light guide portion 44 from which sunlight Ls concentrated by the pillar-shaped light guide portion 44 is output to the solar cell element 20 is formed so that output sunlight Ls is certainly incident to a light receiving surface (a light receiving region, not shown) of the solar cell element 20. Therefore, the sunlight Ls incident to the pillar-shaped light guide portion 44 is further uniformly concentrated so that the solar cell element 20 can be irradiated with such uniformly concentrated sunlight Ls.

Around the pillar-shaped light guide portion 44, the light shielding plate 43 is disposed to shield the concentrated sunlight Ls. The pillar-shaped light guide portion 44 is inserted to the inserting hole 43h of the light shielding plate 43 so as to penetrate the light shielding plate 43. Therefore, if the sunlight Ls concentrated by the concentrating lens 11 is deviated the range of the top surface of the pillar-shaped light guide portion 44, the mounting substrate 21, the connecting wiring 35 and the like are not irradiated with the sunlight Ls deviated from the light path, thus it is possible to prevent generation of damage in the mounting substrate 21 and its surroundings (the connecting wiring 35 and the resin sealing portion 33 (see FIGS. 4A and 4B)).

The pillar-shaped light guide portion 44 is fixed to the surface of the solar cell element 20 by the attaching portion 45. The attaching portion 45 is formed, for example, a light transmitting adhesive such as silicone resin, and easily adheres and fix the pillar-shaped light guide portion 44 to the solar cell element 20. The attaching portion 45 is filled in the air layer between the solar cell element 20 and the pillar-shaped light guide portion 44. Thus, optical loss by difference in the refractive index can be prevented and the surface of the solar cell element 20 can be protected.

The light shielding plate 43 is fastened to the heat diffusion plate 30 via the fastening members (not shown) such as rivets. The light shielding plate 43 is preferably formed by the same metal material as the heat diffusion plate 30. Such a same metal material that forms the light shielding plate 43 and the heat diffusion plate 30 is preferably aluminum or aluminum alloy.

If the heat diffusion plate 30 is made of a different material (metal material) from a metal material of the shielding plate 43, their coefficients of linear expansion are different from each other. Then, the inserting hole 43h of the light shielding plate 43 and the pillar-shaped light guide portion 44 interfere with each other by heat expansion. Thus, stress is applied to the attaching portion 45, and the attaching portion 45 may be broken.

In contrast, in the present variation example, the heat diffusion plate 30 and the light shielding plate 43 are formed by the same metal material, it is possible to suppress the interference between the inserting hole 43h of the light shielding plate 43 (for example, made of a metal material) and the pillar-shaped light guide portion 44 (for example, made of a glass material) caused by the difference in the coefficient of linear expansion. Thereby, the stress applied to the attaching portion 45 that attaches the pillar-shaped light guide portion 44 to the solar cell element 20 can be suppressed. Thus, it is possible to prevent the solar cell element 20 or the optical system (the pillar-shaped light guide portion 44 and the attaching portion 45) from being damaged.

Hereinafter, description will be given on a method for manufacturing the concentrator photovoltaic device 1 according to the present embodiment.

First, the solar cell elements 20 are mounted on the respective mounting substrates 21. That is, the rear surface electrodes (not shown) of the respective solar cell elements 20 are adhered to the respective first conductors 23b. The rear surface electrode is, for example, made of silver, and for example soldered, to the first conductor 23b. The plurality of solar cell elements 20 are connected to the respective first conductors 23b, and then, the front surface electrodes 20s are connected to the respective second conductors 23w by the respective connecting members 25.

Next, the mounting substrates 21 on which the respective solar cell elements 20 are mounted are mounted on the corresponding heat diffusion plates 30. Thus, the mounting substrates 21 are adhered and fixed to the corresponding heat diffusion plate 30 via the adhering-fixing portions 28 formed by an adhesive.

To the process in which the mounting substrates 21 are mounted on the heat diffusion plate 30, either of two methods can be applied. That is, it is possible to apply either the method in which the mounting substrates 21 are mounted one-by-one on the predetermined positions (the positions on which the solar cell elements 20 are disposed) of the heat diffusion plate 30 using a jig (not shown) corresponding to the heat diffusion plate 30, or the method in which the heat diffusion plate 30 is automatically pitch-fed (not shown) in the longitudinal direction so that the mounting substrates 21 are mounted on the predetermined positions of the heat diffusion plate 30.

Description will be given on the case in which the jig is used. The jig has, for example, a plate shape, and through holes into which the mounting substrates 21 are inserted is formed at the positions where the solar cell elements 20 are disposed. That is, the jig including openings (through holes) for positioning the plural (five) mounting substrates 21 is disposed on the heat diffusion plate 30. For the positioning of the jig and the heat diffusion plate 30, the plate mounting holes 30h formed in the heat diffusion plate 30 (see FIGS. 1B and 2A) can be used.

For example, protrusions corresponding to the plate mounting holes 30h or jig holes (positioning reference holes) common to the plate mounting holes 30h are formed in the jig. Thus, the through holes (openings) in which the mounting substrates 21 should be disposed can be positioned relative to the heat diffusion plate 30 with high accuracy. The outer shape of the jig has an outer periphery that is substantially the same as or slightly smaller than the heat diffusion plate 30 so as to be positioned easily and with high accuracy at the heat diffusion plate 30. Using the jig can simplify the positioning of the mounting substrates 21 relative to the heat diffusion plate 30.

After positioning the jig at the heat diffusion plate 30, the adhesive is applied on the surface of the heat diffusion plate 30 via the through holes of the jig for forming the adhering-fixing portions 28. After that, the mounting substrate 21 on which the solar cell element 20 is mounted is placed on the adhesive. Thus, the mounting substrate 21 is placed on the heat diffusion plate 30 via the adhering-fixing portion 28.

Specifically, the adhesive forming the adhering-fixing portions 28 is applied by an appropriate amount by a dispenser through the through holes of the jig to the heat diffusion plate 30. The mounting substrates 21 are positioned at the openings of the jig so as to be adhered and fixed to the heat diffusion plate 30. Therefore, the positions of the mounting substrates 21 relative to the plate mounting holes 30h of the heat diffusion plate 30 are accurately set, and consequently, the mounting substrate 21 is positioned with high accuracy relative to the heat diffusion plate 30.

Furthermore, the solar cell elements 20 (the mounting substrates 21) are adhered to the heat diffusion plate 30 by the adhering-fixing portions 28. Thus, there is no need of the fastening member (the fastening region) to fix the mounting substrates 21 to the heat diffusion plate 30. Consequently, the mounting process of the mounting substrates 21 relative to the housing frame 40 (the bottom portion 40b) can be simplified.

Description will be given on the case in which the automatic pitch-feeding is used. It is sufficient to provide with a feeding mechanism that feeds the heat diffusion plate 30 in the longitudinal direction and a dispenser that applies the adhesive forming the adhering-fixing portions 28 to the heat diffusion plate 30, and furthermore, to provide with a similar feeding mechanism and a bonder that mounts the mounting substrates 21 on the adhesive applied to the heat diffusion plate 30. By the automatic pitch-feeding, the positioning can be performed with rapidity.

After the mounting substrates 21 have been mounted on the heat diffusion plate 30, the connecting wirings 35 (the connecting wirings 35d, see FIG. 1B) couple (connect) between the respective mounting substrates 21 mounted on the heat diffusion plate 30. Specifically, one mounting substrate 21 (the conductor 23) and the adjacent mounting substrate 21 (the conductor 23) are connected by the connecting wiring 35d. The heat diffusion plate 30 is moved in the row direction Dx, thus the connecting wirings 35d can be easily connected to the respective mounting substrates 21.

The heat diffusion plate 30 on which the mounting substrates 21 are mounted and the connecting wirings 35 (the connecting wirings 35d) are connected to the respective mounting substrates 21 is attached to the bottom portion 40b of the housing frame 40 via the plate mounting holes 30h and the plate fixing holes 40s. That is, the heat diffusion plate 30 is mounted on (fastened to) the housing frame 40. In the present embodiment, the size SPx of the heat diffusion plate 30 corresponds to the number of the concentrating lenses 11 of the concentrating lens array 10 in the row direction Dx. Thus, the number of the heat diffusion plates 30 is reduced so that the attachment of the heat diffusion plates 30 to the housing frame 40 can be simplified, thereby improving productivity.

The positioning of the heat diffusion plate 30 at the housing frame 40 (bottom portion 40b) can be easily performed by the plate mounting holes 30h and the plate fixing holes 40s. After the heat diffusion plates 30 have been fixed (attached) to the bottom portion 40b, the connecting wirings 35p that are the wirings between the respective heat diffusion plates 30 are connected to the respective solar cell elements 20 mounted on the heat diffusion plates 30 adjacent to each other. Also, the power extraction wiring 39 is connected to the endmost solar cell element 20 among the solar cell elements 20 that are connected to each other in series.

After that, the positioning projections 12p of the concentrating lens array 10 are positioned at the positioning holes 40h of the flange portion 40g (the wall portion 40w), thus the concentrating lens array 10 is fixed to the flange portion 40g that is provided opposed to the side of the housing frame 40 (the bottom portion 40b) to which the heat diffusion plates 30 are attached.

The resin sealing portions 33 are formed by applying, for example, silicone resin, after wiring of the connecting wirings 35 (the connecting wirings 35d and the connecting wirings 35p) has been completed.

Also, after the heat diffusion plates 30 have been attached to the bottom portion 40b of the housing frame 40, the light shielding plate 43, the pillar-shaped light guide portion 44 and the attaching portion 45 are formed as follows, for example. First, the light shielding plate 43 is positioned at and attached to the heat diffusion plate 30. Next, a light transmitting adhesive (light transmitting resin) is applied on the surface of the solar cell element 20 via the inserting hole 43h of the light shielding plate 43, and the pillar-shaped light guide portion 44 is made contact with the applied light transmitting adhesive so that the light transmitting adhesive cures. Thus, the attaching portion 45 can be formed.

It is possible to attach the heat diffusion plate 30 to the bottom portion 40b of the housing frame 40 after the light shielding plate 43, the pillar-shaped light guide portion 44 and the attaching portion 45 are attached to the heat diffusion plate 30 in advance. The order of each of the steps to form the light shielding plate 43, the pillar-shaped light guide portion 44 and the attaching portion 45 can be changed relative to the other steps, if necessary.

After completion of the steps inside the housing frame 40, the concentrating lens array 10 is attached to the flange portion 40g that serves as a top surface of the housing frame 40. In the present embodiment, the positioning holes 40h are formed in advance in the flange portion 40g of the housing frame 40. And on the concentrating lens array 10, the positioning projections 12p are formed in advance. The positioning projection 12p is simultaneously formed when the concentrating lens 11 is formed on the light transmitting substrate 12.

When the concentrating lens array 10 is attached to the flange portion 40g, the adhesive made of silicone resin (not shown) is applied in advance on the flange portion 40g. After that, images of the positioning projections 12p and the positioning holes 40h are recognized by a CCD (Charge Coupled Device) camera, and the concentrating lens array 10 is temporary positioned with several mm apart from the upper surface of the flange portion 40g of the housing frame 40. The temporary positioned concentrating lens array 10 is slowly lowered, and the concentrating lens array 10 (the positioning projections 12p) is positioned at and adhered to the flange portion 40g (positioning holes 40h).

Since the positioning is performed using the positioning projections 12p and the positioning holes 40h, the positioning of the solar cell element 20 and the concentrating lens 11 can be easily performed. That is, the optical axis Lax (see FIG. 2B) of the concentrating lens 11 can be accurately positioned at the solar cell element 20, and degradation of photoelectric conversion efficiency by deviation of the optical axis can be suppressed. Thus, the concentrator photovoltaic device 1 having high power output can be obtained.

As described above, the method for manufacturing the concentrator photovoltaic device 1 according to the present embodiment is the method for manufacturing the concentrator photovoltaic device that includes: the solar cell elements 20 that photoelectrically convert sunlight Ls concentrated by the concentrating lenses 11; the mounting substrates 21 that have respective conductors to which respective solar cell elements are connected, the mounting substrates 21 on which the respective solar cell elements 20 are mounted; a concentrating lens array 10 formed by the concentrating lenses 11 respectively arranged in the row direction Dx and the column direction Dy; a heat diffusion plate 30 that diffuses heat from the mounting substrates 21, the mounting substrates 21 being mounted on the heat diffusion plate 30; and a housing frame 40 on which the heat diffusion plate 30 is mounted.

The method for manufacturing the concentrator photovoltaic device 1 includes the steps of: mounting the mounting substrates 21, on which the respective solar cell elements 20 are mounted, on the heat diffusion plate; connecting one of the conductors 23 of the one mounting substrate 21 that is mounted on the heat diffusion plate 30 to an adjacent conductor 23 of the mounting substrate 21 by a connecting wiring 35 (connecting wiring 35d); and mounting the heat diffusion plate 30, on which the conductors 23 are connected by the connecting wirings 35, on the housing frame 40 so that the longitudinal direction of the heat diffusion plate 30 corresponds to the row direction Dx of the concentrating lens array 10.

Therefore, in the method for manufacturing the concentrator photovoltaic device 1, the heat diffusion plate 30 on which the mounting substrates 21 are mounted is mounted on (attached to) the housing frame 40 so that the longitudinal direction of the heat diffusion plate 30 corresponds to the row direction Dx of the concentrating lens array 10. Thus, it is possible to effectively manufacture, with high productivity, the concentrator photovoltaic device 1 having high heat dissipation.

The present invention can be embodied and practiced in other different forms without departing from the spirit and essential characteristics thereof. Therefore, the above-described embodiment is considered in all respects as illustrative and not restrictive. The scope of the present invention is indicated by the appended claims rather than by the foregoing description. All variations and modifications falling within the equivalency range of the appended claims are intended to be embraced therein.

This application claims priority on Patent Application No. 2011-144707 filed in Japan on Jun. 29, 2011, which is hereby incorporated by reference in its entirety.

### REFERENCE SIGNS LIST

1 concentrator photovoltaic device
10 concentrating lens array
11 concentrating lens
12 light transmitting substrate
12p positioning projection
20 solar cell element
20s front surface electrode
21 mounting substrate
22 insulator
23 conductor
23b first conductor
23w second conductor
24 rear surface conductor
25 connecting member
28 adhering-fixing portion
30 heat diffusion plate
30h plate mounting hole
33 resin sealing portion
35 connecting wiring
35d connecting wiring
35p connecting wiring
36 connecting conductor
37 insulating coating material
39 power extraction wiring
40 housing frame
40b bottom portion
40g flange portion
40h positioning hole
40s plate fixing hole
40w wall portion
41 fastening member
43 light shielding plate
43h inserting hole
44 pillar-shaped light guide portion
45 attaching portion
Dx row direction
Dy column direction
Lax optical axis
Ls sunlight
MP welding portion
SLx, SLy, SPx, SPy size

1. A concentrator photovoltaic device, comprising:
concentrating lenses concentrating sunlight;
solar cell elements photoelectrically converting the sunlight concentrated by the respective concentrating lenses; and
mounting substrates on which the respective solar cell elements are mounted,
the concentrator photovoltaic device further comprising a concentrating lens array formed by the concentrating lenses respectively arranged in a row direction and a column direction, and a heat diffusion plate that diffuses heat from the mounting substrates, the mounting substrates being mounted on the heat diffusion plate,
wherein the heat diffusion plate is disposed facing the concentrating lenses arranged in the row direction, and
wherein a size of the heat diffusion plate in the row direction is two or more times as large as a size of each of the concentrating lenses in the row direction, and a size of the heat diffusion plate in the column direction is smaller than a size of each of the concentrating lenses in the column direction.

2. The concentrator photovoltaic device according to claim 1, further comprising a housing frame on which the heat diffusion plate is mounted.

3. The concentrator photovoltaic device according to claim 1, further comprising adhering-fixing portions that adhere and fix the mounting substrates to the heat diffusion plate.

4. The concentrator photovoltaic device according to claim 1, wherein the mounting substrates include conductors to which the respective solar cell elements are connected and insulators on which the respective conductors are disposed.

5. The concentrator photovoltaic device according to claim 4, wherein a volume resistivity of the insulators is 10¹² Ω·cm or more.

6. The concentrator photovoltaic device according to claim 5, wherein the insulators are made of a ceramic material.

7. The concentrator photovoltaic device according to claim 6, wherein the ceramic material is aluminum nitride.

8. The concentrator photovoltaic device according to claim 4, further comprising a connecting wiring that connects one of the conductors of the mounting substrates to an adjacent one of the conductors of the mounting substrates,
wherein the connecting wiring includes a connecting conductor that connects the conductors to each other and an insulating coating material that coats the connecting conductor.

9. The concentrator photovoltaic device according to claim 8, wherein the connecting conductor is disposed in a form of a beam between the conductors.

10. The concentrator photovoltaic device according to claim 8, wherein the connecting conductor is connected to the conductors by welding.

11. The concentrator photovoltaic device according to claim 8, wherein the conductors and the connecting conductor are formed by the same metal material.

12. The concentrator photovoltaic device according to claim 8, wherein the heat diffusion plate and the connecting conductor are formed by the same metal material.

13. The concentrator photovoltaic device according to claim 4, further comprising:
connecting members formed by a metal material,
wherein the conductors are made up of respective first conductors on which the respective solar cell elements are mounted and respective second conductors that are disposed separated apart from the respective first conductors,
wherein the solar cell elements include front surface electrodes that are formed on respective front surfaces of the solar cell elements, and
wherein the second conductors and the front surface electrodes are respectively connected by the connecting members.

14. The concentrator photovoltaic device according to claim 11, wherein the metal material is aluminum or aluminum alloy.

15. The concentrator photovoltaic device according to claim 3, wherein the adhering-fixing portions are formed by a synthetic resin material having a heat conductivity of 1 W/m·K or more.

16. The concentrator photovoltaic device according to claim 1, further comprising:
a pillar-shaped light guide portion guiding sunlight concentrated by each of the concentrating lenses to a corresponding one of the solar cell elements; and
a light shielding plate having an inserting hole into which the pillar-shaped light guide portion is inserted, and being fastened to the heat diffusion plate so as to shield sunlight.

17. The concentrator photovoltaic device according to claim 16, wherein the light shielding plate is formed by the same metal material as used for the heat diffusion plate.

18. A method for manufacturing a concentrator photovoltaic device, the concentrator photovoltaic device comprising:
solar cell elements photoelectrically converting sunlight concentrated by respective concentrating lenses;
mounting substrates having respective conductors to which the respective solar cell elements are connected, the mounting substrates on which the respective solar cell elements are mounted;
a concentrating lens array formed by the concentrating lenses respectively arranged in a row direction and a column direction;
a heat diffusion plate that diffuses heat from the mounting substrates, the mounting substrates being mounted on the heat diffusion plate; and
a housing frame on which the heat diffusion plate is mounted,
the method for manufacturing the concentrator photovoltaic device comprising the steps of:
mounting, on the heat diffusion plate, the mounting substrates on which the respective solar cell elements are mounted;
connecting one of the conductors of the mounting substrates mounted on the heat diffusion plate to an adjacent one of the conductors of the mounting substrates by a connecting wiring, and
mounting the heat diffusion plate, to which the conductors are connected by the connecting wirings, on the housing frame so that a longitudinal direction of the heat diffusion plate corresponds to the row direction of the concentrating lens array.

19. The method for manufacturing the concentrator photovoltaic device according to claim 18,
wherein the heat diffusion plate is disposed facing the concentrating lenses disposed in the row direction,
wherein a size of the heat diffusion plate in the row direction is two or more times as large as a size of each of the concentrating lenses in the row direction, and
wherein a size of the heat diffusion plate in the column direction is smaller than a size of each of the concentrating lenses in the column direction.
